(19) United States
(12) Patent Application Publication
(10) Pub. No.: US 2025/0343121 A1
(43) Pub. Date: Nov. 6, 2025

(54) INTERPOSER MODULE INCLUDING INTERCONNECTS WITH ALLOY BARRIER, PACKAGE STRUCTURE INCLUDING THE INTERPOSER MODULE AND METHODS OF MAKING THE SAME

(71) Applicant: Taiwan Semiconductor Manufacturing Company Limited, Hsinchu (TW)

(72) Inventors: Jian-Yang HE, Tainan City (TW); Ming-Che HO, Tainan City (TW); Hung-Jui KUO, Hsinchu City (TW)

(21) Appl. No.: 18/655,241

(22) Filed: May 4, 2024

(51) Int. Cl. H01L 23/498; H01L 21/48; H01L 23/00; H01L 23/055; H01L 23/31; H01L 23/373; H01L 25/065

(52) U.S. Cl. CPC H01L 23/49822; H01L 21/4857; H01L 23/055; H01L 23/3135; H01L 23/373; H01L 24/05; H01L 24/11; H01L 24/13; H01L 24/16; H01L 24/81; H01L 25/0655; H01L 2224/05562; H01L 2224/05573; H01L 2224/05647; H01L 2224/05666; H01L 2224/11462; H01L 2224/13083; H01L 2224/13147; H01L 2224/1316; H01L 2224/13184; H01L 2224/16227; H01L 2224/16507; H01L 2224/81193; H01L 2224/81815; H01L 2924/16235; H01L 2924/16251; H01L 2924/2064; H01L 2924/381; H01L 2924/384

(57) ABSTRACT

An interposer module includes an interposer, a semiconductor die on the interposer, and a plurality of interconnects connecting the interposer to the semiconductor die, wherein the plurality of interconnects includes a first interconnect portion including a first alloy barrier, a second interconnect portion including a second alloy barrier, and a solder joint connecting the first interconnect portion to the second interconnect portion.

### BACKGROUND

Metal bumps are commonly used as interconnects in advanced packaging. A metal bump (e.g., copper bump) may include, for example, a C4 (controlled-collapse chip connection) bump and a C2 (chip connection) bump which is smaller than the C4 bump. The C2 bump may be commonly referred to as a “microbump.”

Metal bumps may include a metal pillar (copper pillar) with a thin nickel layer barrier (e.g., nickel diffusion barrier) and a tin-silver solder cap. Metal bumps may be formed on a surface of a semiconductor die in a series of steps.

In particular, the metal bumps may be formed by first depositing an under-bump metallurgy (UBM) layer on a bonding pad. Then, a metal layer (e.g., copper layer) may be formed on the UBM layer using an electrochemical deposition (ECD) system. The nickel diffusion barrier may then be formed on the metal layer, and the solder cap may then be formed on the nickel diffusion barrier.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of an interposer module according to one or more embodiments.

FIG. 1B is a detailed vertical cross-sectional view of a pitch between interconnects in the interposer module according to one or more embodiments.

FIG. 1C is a detailed vertical cross-sectional view of interconnect in the interposer module according to one or more embodiments.

FIG. 2A is a vertical cross-sectional view of an intermediate structure including a portion of the interposer (e.g., organic interposer) on a first carrier substrate (e.g., carrier wafer) according to one or more embodiments.

FIG. 2B is a vertical cross-sectional view of an intermediate structure including the upper passivation layer on the chip-side surface of the interposer, according to one or more embodiments

FIG. 2C is a vertical cross-sectional view of an intermediate structure including openings in the upper passivation layer on the chip-side surface of the interposer, according to one or more embodiments.

FIG. 2D is a vertical cross-sectional view of an intermediate structure including the first seed layer on the upper passivation layer on the chip-side surface of the interposer, according to one or more embodiments.

FIG. 2E is a vertical cross-sectional view of an intermediate structure including a patterned photoresist layer on the first seed layer, according to one or more embodiments.

FIG. 2F is a vertical cross-sectional view of an intermediate structure including first bumps in the openings of the patterned photoresist layer, according to one or more embodiments.

FIG. 2G is a vertical cross-sectional view of an intermediate structure including first bumps on the first seed layer, according to one or more embodiments.

FIG. 2H is a vertical cross-sectional view of an intermediate structure including first bumps on the first seed layer, according to one or more embodiments.

FIG. 2I is a vertical cross-sectional view of an intermediate structure including the first bumps after a reflow process, according to one or more embodiments.

FIG. 2J is a vertical cross-sectional view of an intermediate structure including the semiconductor dies positioned over the interposer, according to one or more embodiments.

FIG. 2K is a vertical cross-sectional view of an intermediate structure including the semiconductor dies positioned over the interposer, according to one or more embodiments.

FIG. 2L is a vertical cross-sectional view of an intermediate structure including the interposer module underfill layer according to one or more embodiments.

FIG. 2M is a vertical cross-sectional view of an intermediate structure including the molding material layer, according to one or more embodiments.

FIG. 2N illustrates a vertical cross-sectional view of an intermediate structure including the plurality of C4 bumps, according to one or more embodiments.

FIG. 3 is a flow chart illustrating a method of making the interposer module according to one or more embodiments.

FIG. 4 is a detailed vertical cross-sectional view of the interconnects in the interposer module having a first alternative design according to one more embodiments.

FIG. 5 is a detailed vertical cross-sectional view of the interconnects in the interposer module having a second alternative design according to one more embodiments.

FIG. 6 is a vertical cross-sectional view of a package structure including the interposer module according to one more embodiments.

FIG. 7A is a vertical cross-sectional view of an intermediate structure including the package substrate having package substrate upper bonding pads and package substrate lower bonding pads, according to one or more embodiments.

FIG. 7B illustrates a vertical cross-sectional view of an intermediate structure in which the interposer module may be mounted on the package substrate, according to one or more embodiments.

FIG. 7C illustrates a vertical cross-sectional view of an intermediate structure in which the package underfill layer may be formed on the package substrate according to one or more embodiments.

FIG. 7D illustrates a vertical cross-sectional view of an intermediate structure in which the TIM layer may be formed on (e.g., attached to) the interposer module according to one or more embodiments.

FIG. 7E illustrates a vertical cross-sectional view of an intermediate structure in which the adhesive layer may be applied to the package substrate according to one or more embodiments.

FIG. 7F illustrates a vertical cross-sectional view of an intermediate structure in which the package lid may be attached to (e.g., mounted on) the package substrate 1 according to one or more embodiments.

FIG. 7G illustrates a vertical cross-sectional view of an intermediate structure in which a plurality of solder balls may be formed on the package substrate 1 according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within the same thickness range.

It may be desirable to reduce a pitch (interconnect pitch) between interconnects (metal bumps such as a microbumps) in an interposer module or semiconductor package. Reducing the interconnect pitch may allow for an increase in input/output (I/O) density and thereby help to fuel the growing demand for heterogenous integration.

Currently, interconnects using a nickel layer barrier may include a limited solder amount for collapsing risk management and less joint necking after intermetallic compound (IMC) formation. In particular, the nickel layer barrier does not resist IMC formation and sidewall wetting effectively. Therefore, the interconnects having a nickel layer barrier may be unable to provide good joint yield and high-temperature solder (HTS) reliability.

In particular, in an interposer module (e.g., system on integrated chips) having interconnects at a 12 μm pitch, the interconnects may suffer serious solder collapsing after a reflow process. The solder collapsing may be moderated by limiting solder amount and plasma treatment for sidewall passivation. Furthermore, joint necking (i.e., tensile deformation) may be observed after HTS since Ni₃Sn₄ IMC formation may be accompanied by solder volume shrinkage.

One or more embodiments of the present disclosure may provide an interconnect including an alloy barrier (barrier metal). In at least one embodiment, the alloy barrier may replace the currently used nickel layer barrier resulting in interconnect with improved reliability. The interconnect may have an ultra-slow IMC growth rate with Sn. This may help to provide a solder amount design limit without experiencing solder collapsing and joint necking. In particular, the alloy barrier may resist IMC formation and sidewall wetting, allowing the alloy barrier to sustain the solder volume without shrinkage. The alloy barrier may also allow for a reduced interconnect pitch (e.g., an interconnect pitch of 40 μm or less or even 12 μm or less).

In at least one embodiment, the interconnect may include a solder joint and a pair of alloy barriers on opposing sides of the solder joint. In particular, the interconnect may include an interposer side bump portion (first interconnect portion), a die side bump portion (second interconnect portion) and a solder joint connecting the die side bump portion to the interposer side bump portion. The interposer side bump portion may include an outer interposer side bump copper layer (first outer metal layer), an inner interposer side bump copper layer (first inner metal layer) and an alloy barrier between the outer interposer side bump copper layer and the inner interposer side bump copper layer. The die side bump portion may include an outer die side bump copper layer (second outer metal layer), an inner die side bump copper layer (second inner metal layer) and an alloy barrier between the outer die side bump copper layer and the inner die side bump copper layer.

A thickness of the alloy barrier may be in a range from 1 μm to 5 μm. A composition of the alloy barrier may include either (1) an iron-based binary alloy with iron in a range from 50 wt % to 90 wt %, or (2) a tungsten-based binary alloy with tungsten in a range from 40 wt % to 50 wt %. The iron-based binary alloy may include, for example, FeNi or FeCo. The tungsten-based binary alloy may include, for example, NiW or CoW. Other suitable iron-based binary alloys and tungsten-based binary alloys may also be used.

After formation of the solder joint (and after reliability testing), a combined thickness of the inner interposer side bump copper layer and the inner interposer side bump copper layer may be less than 50% of a thickness of the solder joint. Further, the solder joint may have a reduced amount of IMC (e.g., not fully IMC) and, therefore, a reduced amount of IMC-related void formation.

It should be noted that that there may be two parts of IMC formation in this embodiment. First, IMC may be formed by the solder joint reacting with the inner die side bump copper layer and/or the inner interposer side bump copper layer at the interface and sidewall. Second, IMC may be formed by solder wetting through sidewall of the inner die side bump copper layer and/or the inner interposer side bump copper layer, then reacting with the alloy barrier. The alloy barrier may, therefore, reduce IMC formation (even though the alloy barrier is not in direct contact with the solder) by resisting the second part of IMC formation.

The solder joint of the interconnect may help to reduce sidewall wetting. Sidewall wetting may occur in two circumstances. First, during solder melting in forming the solder joint. Second, during thermal treatment in downstream processes and reliability testing.

The solder joint of the interconnect may have an increased sidewall angle compared to a current interconnect (e.g., a sidewall angle of about 12° to 15° compared to a sidewall angle of 10° in current interconnects). This may allow the interconnect to realize a reduced amount of sidewall wetting compared to current interconnects.

In alternative designs of the interconnect, the alloy barriers on opposing sides of the solder joint may contact the solder joint. In particular, in a first alternative design, the inner die side bump copper layer and the inner interposer side bump copper layer may be omitted. That is, the die side bump portion may include an outer die side bump copper layer and an alloy barrier between the solder joint and the outer die side bump copper layer. The interposer side bump portion may include an outer interposer side bump copper layer and an alloy barrier between the solder joint and the outer interposer side bump copper layer.

In a second alternative design, the inner die side bump copper layer and the inner interposer side bump copper layer may be omitted, and the outer die side bump copper layer and the outer interposer side bump copper layer may be omitted. That is, the die side bump portion may include an alloy barrier between the solder joint and die, and the interposer side bump portion may include an alloy barrier between the solder joint and the interposer.

In the first and second alternative designs, the solder wetting to barrier sidewall length may be less than or equal to about 10% of alloy barrier thickness. Further, in the first and second alternative designs, a total IMC thickness (e.g., combined thickness of the second IMC layer formed at upper part of solder joint and first IMC layer formed at lower part of solder joint) may be less than or equal to about 10% of solder joint thickness.

In summary, novel alloy type barrier metals may be implemented for fine-pitch interconnects (e.g., an interconnect pitch of 40 μm or less) to improve joint yield and HTS reliability by ultra slow IMC growth rate with Tin (Sn). The alloy metal composition may include either an iron-based alloy or a tungsten-based alloy, with controlled alloy ratios.

There may be several advantages to the design of the present disclosure. First, the design may enable interconnect pitch downscaling resulting in a reduced solder amount and reduced standoff height (e.g., the Z-axis distance between a die and interposer such as between a top die surface and a bottom wafer surface) and with a wider joint process window. A smaller interconnect can only sustain less melting solder which is limited by surface tension. Thus, as the interconnect pitch is reduced, the solder amount may need to be reduced. As the solder amount is reduced, the IMC formation rate may become critical since solder may be consumed in the formation of IMC.

As a second advantage, the design may provide a stable microstructure after reliability (TC, HTS) due to an ultra-low IMC growth rate resulting in less solder necking (joint volume shrinkage). As a third advantage, there may be no wait time concern for joint process (thermocompression bonding (TCB), vapor reflow (VR), or micro reflow (MR)) due to less solder consumption. As a fourth advantage, a uniform joint shape and good joint yield may be achieved due to less solder sidewall wetting.

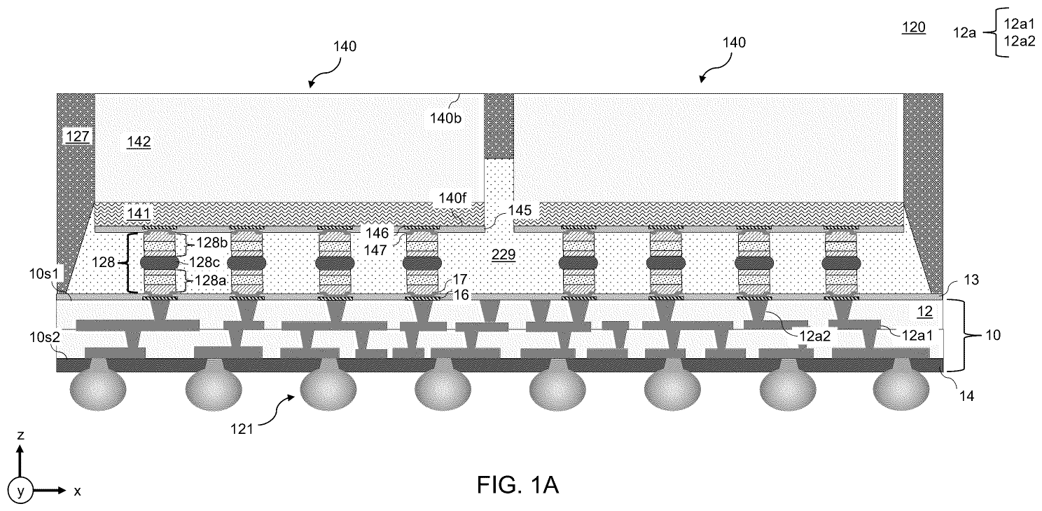

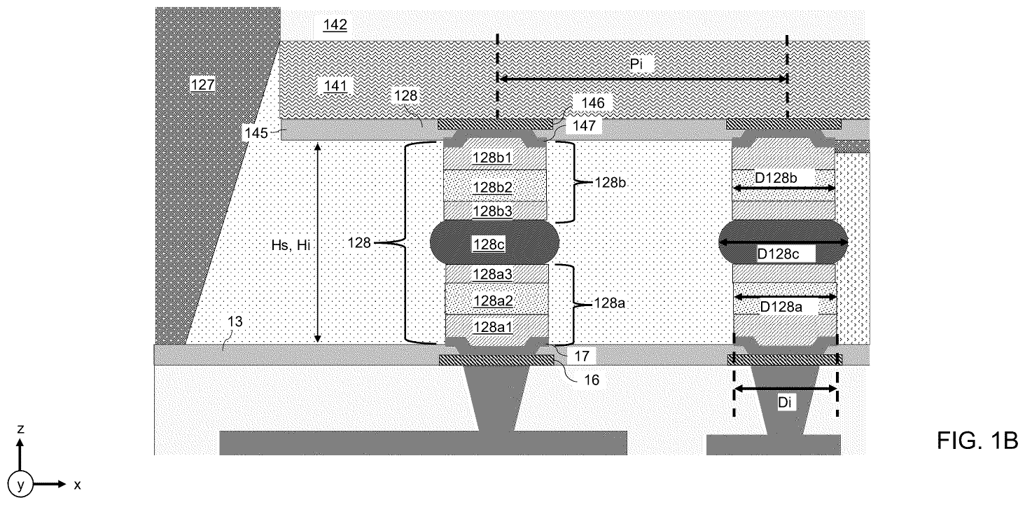

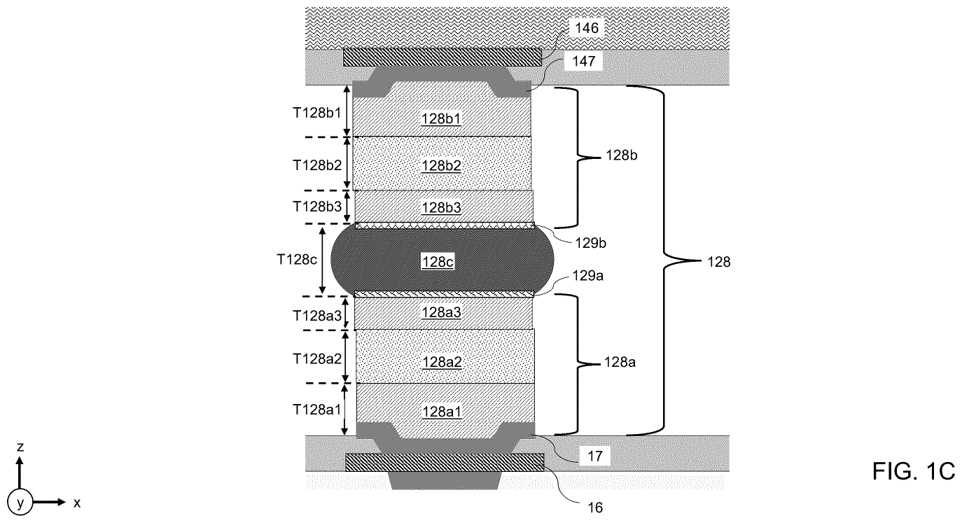

FIG. 1A is a vertical cross-sectional view of an interposer module 120 according to one or more embodiments. FIG. 1B is a detailed vertical cross-sectional view of a pitch Pᵢ between interconnects 128 in the interposer module 120 according to one or more embodiments. FIG. 1C is a detailed vertical cross-sectional view of interconnect 128 in the interposer module 120 according to one or more embodiments.

As illustrated in FIG. 1A, the interposer module 120 may include one or more semiconductor dies 140 on an interposer 10. Although the interposer module 120 is illustrated as including a particular number of semiconductor dies having a particular arrangement, the number of semiconductor dies and the arrangement of the semiconductor dies is not limited to any particular number and arrangement. In particular, the interposer module 120 may include any number and arrangement of semiconductor dies.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of dielectric layers 12 and a plurality of redistribution layers 12a stacked alternately. The number of the dielectric layers 12 and/or the number of redistribution layers 12a in the interposer 10 are not limited by the disclosure. In at least one embodiment, the dielectric layers 12 may include, for example, polyimide (PI), epoxy resin, acrylic resin, phenol resin, benzocyclobutene (BCB), polybenzoxazole (PBO), or any other suitable polymer-based dielectric material. A thickness of the dielectric layers 12 may be in a range from 4 μm to 60 μm. Other thicknesses of the dielectric layers 12 may be within the contemplated scope of disclosure.

The redistribution layers 12a may include conductive materials. The conductive materials may include, for example, one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

The redistribution layers 12a may include metallic connection structures, such as metallic structures that provide electrical connection between nodes in the structure. The redistribution layers 12a may include a metallic seed layer (not shown) and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 μm to 40 μm, such as from 4 μm to 10 μm, although lesser or greater thicknesses may also be used.

In at least one embodiment, the redistribution layers 12a may include a plurality of metal traces 12a1 (metal lines) and a plurality of metal vias 12a2 connecting the plurality metal traces 12a1 to each other. The metal traces 12a1 may be respectively located on the dielectric layers 12, and may extend in the x-direction (first horizontal direction) and y-direction (second horizontal direction) on an upper surface of the dielectric layers 12.

One or more interposer bonding pads 16 may be formed on the chip-side surface 10s1 of the interposer 10. The interposer bonding pads 16 may be formed, for example, of metals, metal alloys, and/or other metal-containing compounds (e.g., Cu, Al, Ni, Mo, Co, Ru, Ti, Ta, W, TiN, TaN, WN, etc.). Other suitable materials may be used in the interposer bonding pads 16.

An upper passivation layer 13 may also be formed on the chip-side surface 10s1 of the interposer 10. The upper passivation layer 13 may cover an outer portion of the interposer bonding pads 16. The upper passivation layer 13 may include silicon oxide, silicon nitride, low-k dielectric materials such as carbon-doped oxides, extremely low-k dielectric materials such as porous carbon doped silicon dioxide, a combination thereof or other suitable material.

A first seed layer 17 may be formed on the upper passivation layer 13. The first seed layer 17 may include a lower portion contacting an upper surface of the interposer bonding pad 16 through an opening in the upper passivation layer 16. The first seed layer 17 may also include an upper portion on an upper surface of the upper passivation layer 13. The first seed layer 17 may serve as a base in a subsequent electroplating process. The first seed layer 17 may include one or more layers and one or more metals such as copper, titanium, etc. In at least one embodiment, the first seed layer 17 may include a copper layer and a titanium layer. Other suitable metals may be used in the first seed layer 17.

The semiconductor dies 140 may be connected to the interposer 10 by one or more interconnects 128. In at least one embodiment, each of the interconnects 128 may include a first interconnect portion 128a including a first alloy barrier, and a second interconnect portion 128b including a second alloy barrier. The interconnects 128 may also include a solder joint 128c connecting the first interconnect portion 128a to the second interconnect portion 128b.

The first interconnect portion 128a may be attached to the chip-side surface 10s1 of the interposer 10. In particular, the first interconnect portion 128a may be formed on the first seed layer 17 that contacts the upper surface of the interposer bonding pad 16. An outer wall of the first interconnect portion 128a may be substantially aligned with an outer wall of the first seed layer 17. The first interconnect portion 128a may be electrically coupled to the redistribution layers 12a through the first seed layer 17 and the interposer bonding pad 16.

One or more die bonding pads 146 may be formed on the frontside 140f of the semiconductor die 140. The die bonding pads 146 may be substantially the same as the interposer bonding pads 16. A die passivation layer 145 may also be formed on the frontside 140f of the semiconductor die 140. The die passivation layer 145 may cover an outer portion of the die bonding pads 146. The die passivation layer 145 may be substantially the same as the upper passivation layer 13 on the interposer 10.

A second seed layer 147 may be formed in the die passivation layer 145. The second seed layer 147 may be substantially the same as the first seed layer 17 on the interposer bonding pad 16. The second seed layer 147 may include a lower portion contacting an upper surface of the die bonding pad 146 through an opening in the die passivation layer 145. The second seed layer 147 may also include an upper portion on an upper surface of the die passivation layer 145.

The second interconnect portion 128b may be attached to a frontside 140f of the semiconductor die 140. In particular, the second interconnect portion 128b may be formed on the second seed layer 147 that contacts the upper surface of the die bonding pad 146. An outer wall of the second interconnect portion 128b may be substantially aligned with an outer wall of the second seed layer 147. The second interconnect portion 128b may be electrically coupled to a front-end-of-line (FEOL) region 141 of the semiconductor die 140 through the second seed layer 147 and the die bonding pad 146.

The solder joint 128c may include a solder material including one or more of tin, copper, silver, bismuth, indium, zinc, and antimony. In at least one embodiment, the solder material may include a tin-silver alloy. In at least one embodiment, the solder material may include a tin-silver-copper alloy including about 3-4% silver, 0.5-0.7% copper, and the balance (95% or more) tin. A fourth metal such as zinc or manganese may be added to the tin-silver-copper alloy. The solder material may have a melting point in a range from 90° C. to 450° C., and more particularly, in a range from about 220° C. to 260° C.

A lower passivation layer 14 may be formed on the board-side surface 10s2 of the interposer 10. The lower passivation layer 14 may also include silicon oxide, silicon nitride, low-k dielectric materials such as carbon-doped oxides, extremely low-k dielectric materials such as porous carbon doped silicon dioxide, a combination thereof or other suitable material.

One or more interposer lower bonding pads (not shown) may also be located on the board-side surface 10s2 of interposer 10. The interposer lower bonding pads may be bonded to and electrically connected to the redistribution layers 12a. The interposer lower bonding pads may be located in the lower passivation layer 14. The lower passivation layer 14 may at least partially cover the interposer lower bonding pads. That is, the interposer lower bonding pads may be at least partially exposed on the board-side surface of the interposer 10. The interposer lower bonding pads may also include, for example, one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

In at least one embodiment, one or more integrated passive devices (IPDs) (not shown) may optionally be located on the board-side surface 10s2 of interposer 10. The IPDs may be bonded to and electrically connected to the redistribution layers 12a. The IPDs may be located in the lower passivation layer 14. The IPDs may include an exposed portion that projects out from the lower passivation layer 14. The IPDs may include one or more electronic components such as resistors, capacitors, inductors, coils, chokes, microstriplines, impedance matching elements, baluns, etc. The IPDs may be electrically coupled to the semiconductor dies 140 through the interposer 10.

As further illustrated in FIG. 1A, one or more C4 bumps 121 may connected to the board-side surface 10s2 of the interposer 10, respectively. The C4 bumps may be connected to the redistribution layers 12a in the lowermost dielectric layer 12 of the interposer. The C4 bumps 121 may alternatively be connected to the interposer lower bonding pads (if present).

In at least one embodiment, the C4 bumps 121 may include underbump metallurgy (UBM) layers (not shown) on the interposer lower bonding pads. The order of material layers within the UBM layers may be selected such that solder material portions may be subsequently bonded to portions of the bottom surface of the UBM layers. The UBM layers may include, but are not limited to, layer stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layers may be in a range from 5 μm to 60 μm, such as from 10 μm to 30 μm, although lesser and greater thicknesses may also be used. A photoresist layer may be applied over the UBM layers, and may be lithographically patterned to form an array of discrete patterned photoresist material portions. An etch process may be performed to remove unmasked portions of the UBM layers. The etch process may be an isotropic etch process or an anisotropic etch process.

In at least one embodiment, the C4 bumps 121 may further include a contact pad (e.g., copper/nickel contact pad) (not shown) on the UBM layers and a solder bump (e.g., SnAg solder bump) on the contact pad. The C4 bumps 121 may allow the interposer module 120 to be connected to a substrate such as a package substrate.

As further illustrated in FIG. 1A, the semiconductor dies 140 may be mounted on the interposer 10 such that a height of the semiconductor dies 140 is substantially the same. Generally, a thickness in the z-direction of each of the semiconductor dies 140 may be substantially the same. Thus, the upper surfaces of each of the semiconductor dies 140 may be substantially coplanar (e.g., formed in the same x-y plane).

The frontside 140f of the semiconductor dies 140 (e.g., semiconductor die upper surface) may face the interposer 10. The semiconductor dies 140 may also include a backside 140b facing away from the interposer 10. The semiconductor dies 140 may also include a back end of line (BEOL) region 142 (e.g., bulk silicon region). The BEOL region 142 may be opposite the FEOL region 141 at the backside 140b of the semiconductor dies 140. The semiconductor dies 140 may be electrically coupled to the redistribution layers 12a in the interposer 10 through the interconnects 128.

An interposer module underfill layer 229 may be formed (e.g., individually or connectively) under and around each of the semiconductor dies 140. The interposer module underfill layer 229 may also be formed around the interconnects 128. The interposer module underfill layer 229 may thereby fix each of the semiconductor dies 140 to the interposer 10. The interposer module underfill layer 229 may be formed of an epoxy-based polymeric material. Other suitable materials may be used for the interposer module underfill layer 229.

The semiconductor dies 140 may each have the same type or a different type. Each of the semiconductor dies 140 may include, for example, a singular semiconductor die, a system on chip die, or a system on integrated chips die, and may be implemented by chip on wafer on substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure.

In at least one embodiment, at least one of the semiconductor dies 140 may include a primary die (e.g., SOC die). Another of the semiconductor dies 140 may include an ancillary die (e.g., memory/SOC die, HBM die, etc.).

The interposer module 120 may also include a molding material layer 127 formed around the semiconductor dies 140. The molding material layer 127 may also be formed on and around the interposer module underfill layer 229. The molding material layer 127 may have an outer sidewall that is substantially aligned with the outer sidewall of the interposer 10.

In at least one embodiment, the molding material layer 127 may be formed on sidewalls (inner sidewall and outer sidewall) of each of the semiconductor dies 140. The molding material layer 127 may be formed between and bonded to the sidewalls of each of the semiconductor dies 140. The molding material layer 127 may also be bonded to the interposer module underfill layer 229 and to the upper passivation layer 13 on the chip-side surface 10s1 of the interposer 10.

As illustrated in FIG. 1A, the molding material layer 127 may include an upper surface that is substantially uniform (e.g., flat). The upper surface of the molding material layer 127 may alternatively or additionally include a recessed portion (not shown) that is recessed in the z-direction from the upper surface of the semiconductor dies 140.

In at least one embodiment, the molding material layer 127 may be formed of a curable material that may cure to form a hard, solid structure. The molding material layer 127 may include, for example, epoxy molding compound (EMC). In at least one embodiment, the molding material layer 127 may include a material that is substantially similar to the interposer module underfill layer 229. In at least one embodiment, the molding material layer 127 may include a polymeric material and in particular, an epoxy-based polymeric material. Other suitable molding materials may be within the contemplated scope of disclosure.

In at least one embodiment, the molding material layer 127 may have a CTE that is substantially similar to a CTE of the interposer 10. In at least one embodiment, the molding material layer 127 may include an added material (e.g., filler material) for improving a property of the molding material layer 127 (e.g., thermal conductivity, CTE, etc.). The added material may include, for example, metal powder, metal oxide powder, etc. Other materials in the molding material layer 127 are within the contemplated scope of the disclosure.

Referring again to FIG. 1B, the first interconnect portion 128a may include a first outer metal layer 128a1 (e.g., outer copper layer) and a first inner metal layer 128a3 (e.g., inner copper layer). The first alloy barrier 128a2 may be between the first outer metal layer 128a1 and the first inner metal layer 128a3. The first alloy barrier 128a2, first outer metal layer 128a1, and first inner metal layer 128a3 may be substantially aligned (in the z-direction) and may have substantially the same diameter.

The second interconnect portion 128b may also include a second outer metal layer 128b1 (e.g., outer copper layer) and a second inner metal layer 128b3 (e.g., inner copper layer). The second alloy barrier 128b2 may be between the second outer metal layer 128b1 and the second inner metal layer 128b3. The second alloy barrier 128b2, second outer metal layer 128b1, and second inner metal layer 128b3 may be substantially aligned (in the z-direction) and may have substantially the same diameter.

As further illustrated in FIG. 1B, the interconnects 128 may be separated by an interconnect pitch Pᵢ. In at least one embodiment, the interconnect pitch Pᵢ may be 40 μm or less, but an interconnect pitch Pᵢ greater than 40 μm is within the contemplated scope of disclosure. The semiconductor die 140 may be separated from the interposer 10 by a standoff height Hₛ. Generally, the standoff height Hₛ may refer to the distance between a bottom surface of the semiconductor die and top surface of the interposer. As illustrated in FIG. 1B, the standoff height Hₛ may refer to the distance between the die passivation layer 145 and the upper passivation layer 13 on the interposer 10.

The standoff height Hₛ between the semiconductor die 140 and interposer 10 may vary depending on the specific design and requirements of the interposer module 120. The standoff height Hₛ may be in a range of a few micrometers to tens of micrometers. The exact value of the standoff height Hₛ may depend on factors such as the bump size, material properties, thermal considerations, and the overall design constraints of the interposer module 120. In at least one embodiment, the standoff height Hₛ may be in a range from 6 μm to 40 μm, but a standoff height Hₛ less than 6 μm or greater than 40 μm is within the contemplated scope of disclosure.

The interconnect 128 may have an interconnect height Hᵢ. The interconnect height Hi may be given as the combined thickness of first interconnect portion 128a, second interconnect portion 128b and solder joint 128c. In at least one embodiment, the interconnect height Hᵢ may be substantially the same as the standoff height Hₛ. Thus, the interconnect height Hᵢ may be in a range from 6 μm to 40 μm, but an interconnect height Hᵢ less than 6 μm or greater than 40 μm is within the contemplated scope of disclosure.

The first interconnect portion 128a may have diameter D₁₂₈ₐ and the second interconnect portion 128b may have a diameter D_{128b}. The interconnect 128 may have an interconnect diameter Dᵢ that is substantially equal to the diameter D₁₂₈ₐ of the first interconnect portion 128a and substantially equal to the diameter D_{128b} of the second interconnect portion 128b. The diameter D_{128c} of the solder joint 128c may be greater than the interconnect diameter Dᵢ. In at least one embodiment, the diameter D_{128c} of the solder joint 128c may be in a range from 5% to 30% greater than the interconnect diameter Dᵢ. The interconnect diameter Dᵢ may be in a range from 1 μm to 20 μm, but an interconnect diameter Dᵢ less than 1 μm or greater than 20 μm is within the contemplated scope of disclosure.

The interconnect height Hᵢ may be less than the interconnect pitch Pᵢ. In at least one embodiment, the interconnect height Hᵢ may be in a range from 25% to 75% of the interconnect pitch Pᵢ. The interconnect diameter Dᵢ may be less than the interconnect height Hᵢ. In at least one embodiment, the interconnect diameter Dᵢ may be in a range from 25% to 75% of the interconnect height Hᵢ.

Referring again to FIG. 1C, the solder layer 128c may have a thickness T_{128c}. The first outer metal layer 128a1 may have a thickness T₁₂₈ₐ₁, the first alloy barrier 128a2 may have a thickness T₁₂₈ₐ₂ and the first inner metal layer 128a3 may have a thickness T₁₂₈ₐ₃. A thickness of the first interconnect portion 128a may be given as a combined thickness of the first outer metal layer 128a1, first alloy barrier 128a2 and first inner metal layer 128a3 (e.g., T₁₂₈ₐ₁+T₁₂₈ₐ₂+T₁₂₈ₐ₃). The thickness T₁₂₈ₐ₂ of the first alloy barrier 128a2 may be in a range from 1 μm to 5 μm. The thickness T₁₂₈ₐ₁ of the first outer metal layer 128a1 may be substantially the same the thickness of the first alloy barrier 128a2. The thickness T₁₂₈ₐ₃ of the first inner metal layer 128a3 may be less than 25% of the thickness T_{128c} of the solder layer 128c. The thickness T_{128c} of the solder layer 128c may be greater than the thickness T₁₂₈ₐ₂ of the first alloy barrier 128a2.

The second outer metal layer 128b1 may have a thickness T_{128b1}, the second alloy barrier 128b2 may have a thickness T_{128b2} and the second inner metal layer 128b3 may have a thickness T_{128b3}. A thickness of the second interconnect portion 128b may be given as a combined thickness of the second outer metal layer 128b1, second alloy barrier 128b2 and second inner metal layer 128b3 (e.g., T_{128b1}+T_{128b2}+T_{128b3}). The thickness T_{128b2} of the second alloy barrier 128b2 may be in a range from 1 μm to 5 μm. The thickness T_{128b1} of the second outer metal layer 128b1 may be substantially the same the thickness T_{128b2} of the second alloy barrier 128b2. The thickness T_{128b3} of the second inner metal layer 128b3 may be less than 25% of the thickness T_{128c} of the solder layer 128c. A combined thickness of the first inner metal layer 128a3 and the second inner metal layer 128b3 may be less than one-half of the thickness T_{128c} of the solder layer 128c (T₁₂₈ₐ₃+T_{128b3}<0.5 T_{128c}). The thickness T_{128c} of the solder layer 128c may be greater than the thickness T_{128b2} of the second alloy barrier 128b2.

The thickness of the first interconnect portion 128a may be substantially the same as the thickness of the second interconnect portion 128b. The thickness T₁₂₈ₐ₁ of the first outer metal layer 128b1 may be substantially the same as the thickness T_{128b1} of the second outer metal layer 128b1. The thickness T₁₂₈ₐ₂ of the first alloy barrier 128a2 may be substantially the same as the thickness T_{128b2} of the second alloy barrier 128b2. The thickness T_{128b3} of the first inner metal layer 128a3 may be substantially the same as the thickness T_{128b3} of the second inner metal layer 128b3.

As further illustrated in FIG. 1C, the interconnect 128 may also include a first IMC layer 129a (lower IMC layer or interposer side IMC layer) at an interface between the solder layer 128c and the first inner metal layer 128a3. The interconnect 128 may also include a second IMC layer 129b (upper IMC layer or semiconductor die side IMC layer) at an interface between the solder layer 128c and the inner semiconductor bump metal layer 128b3. In at least one embodiment, a combined thickness of the first IMC layer 129a and second IMC layer 129b may be less than the thickness T_{128c} of the solder layer 128c. In at least one embodiment, the combined thickness of the first IMC layer 129a and second IMC layer 129b may be less than or equal to 10% of the thickness T_{128c} of the solder layer 128c.

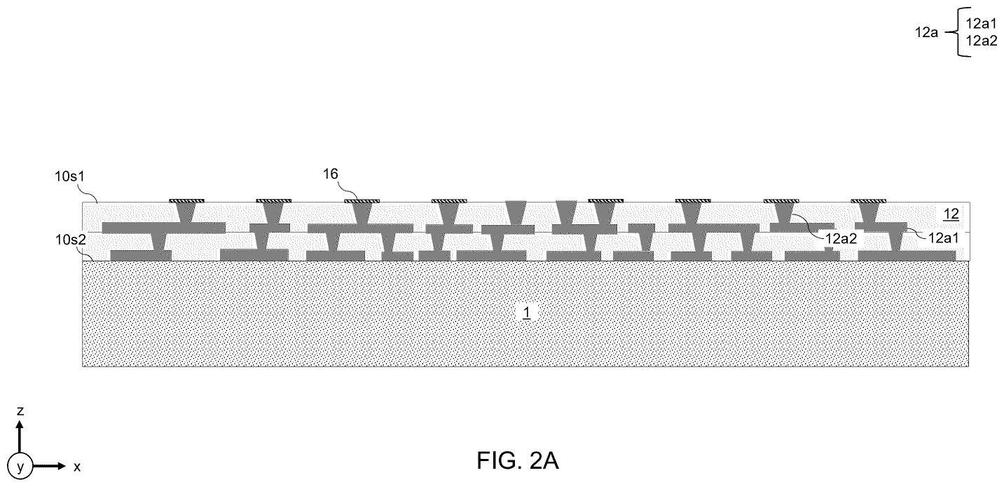

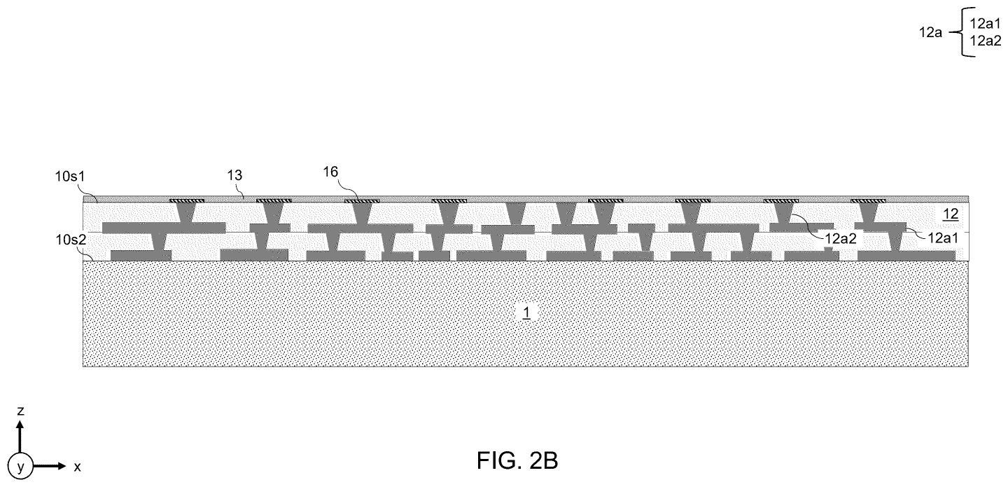

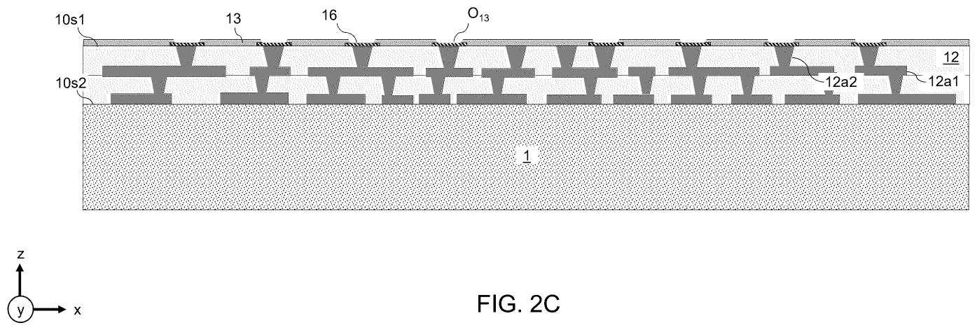

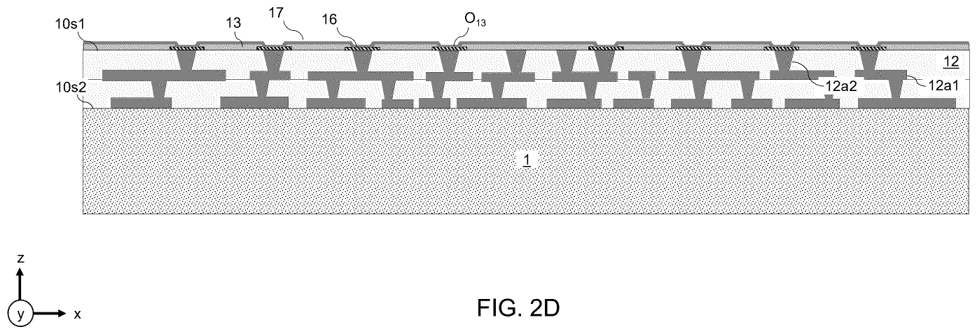

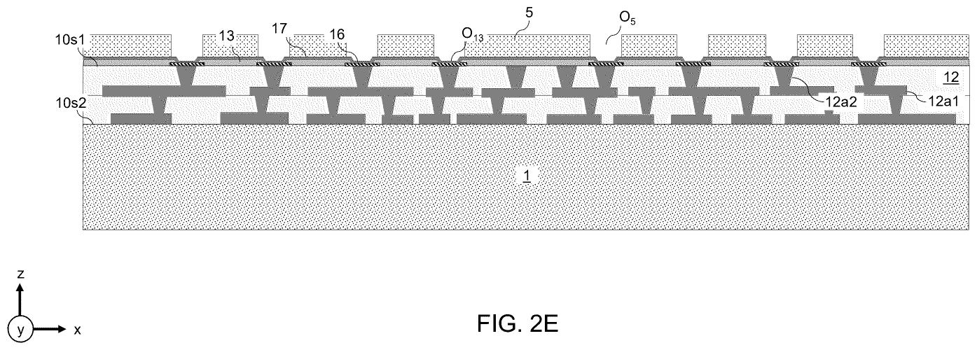

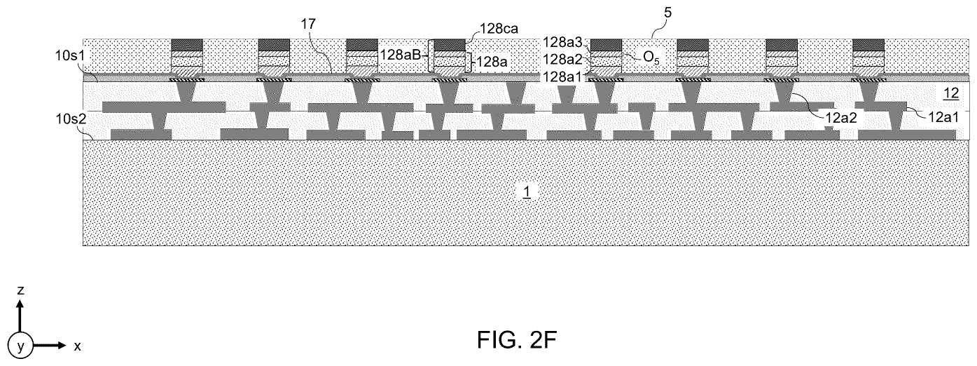

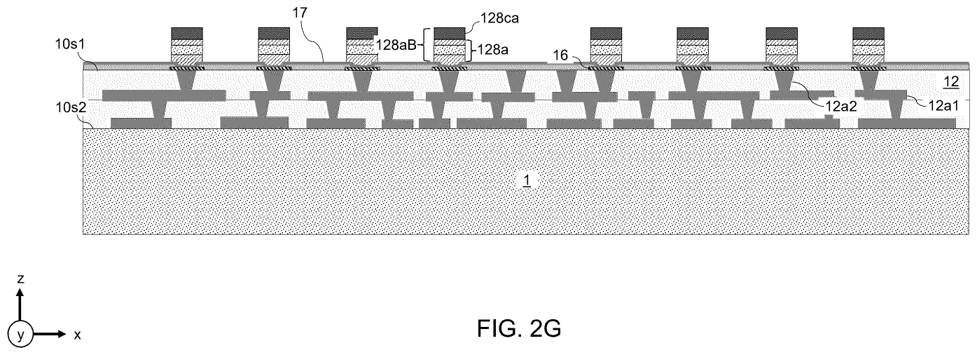

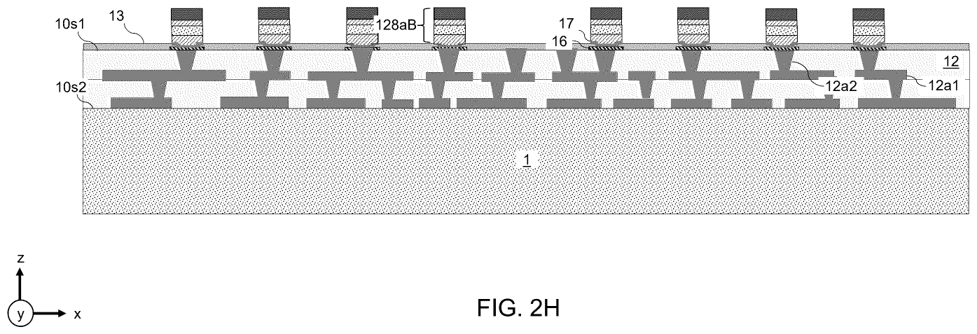

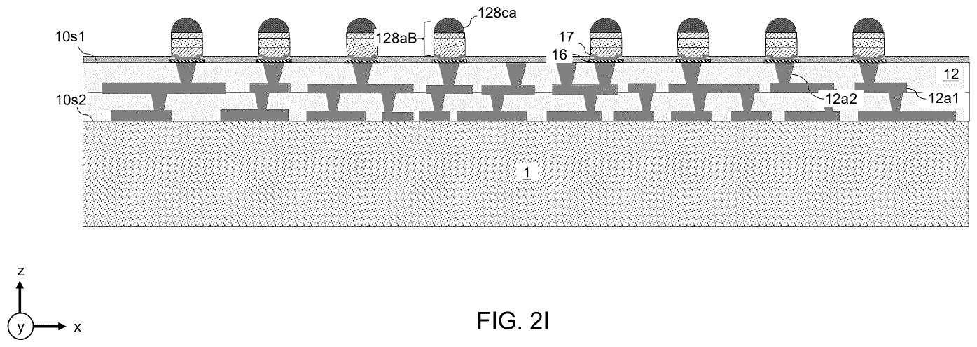

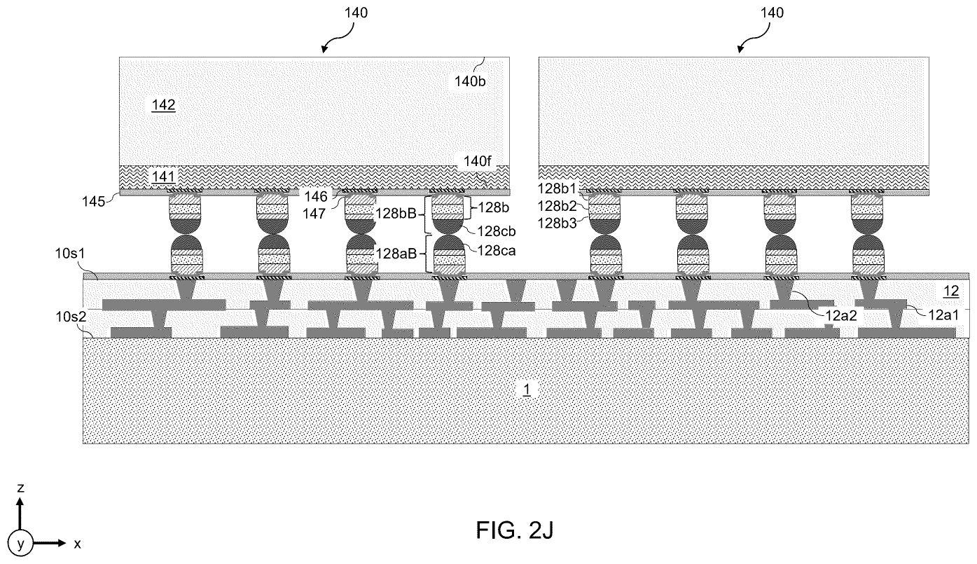

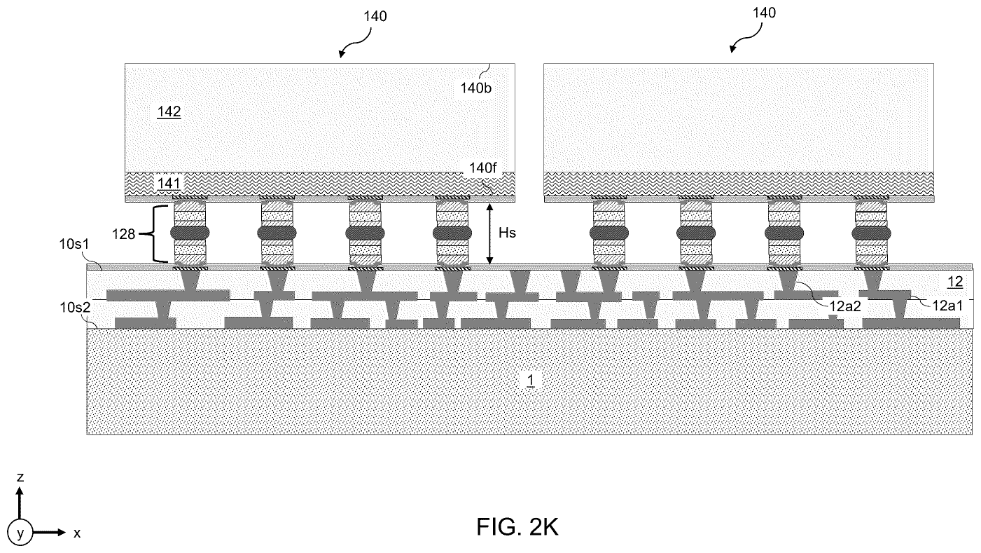

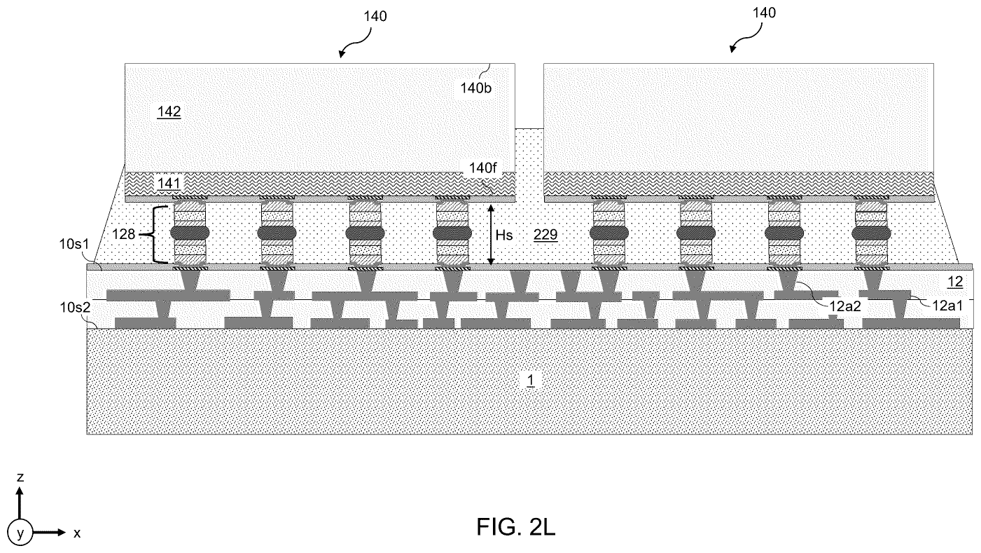

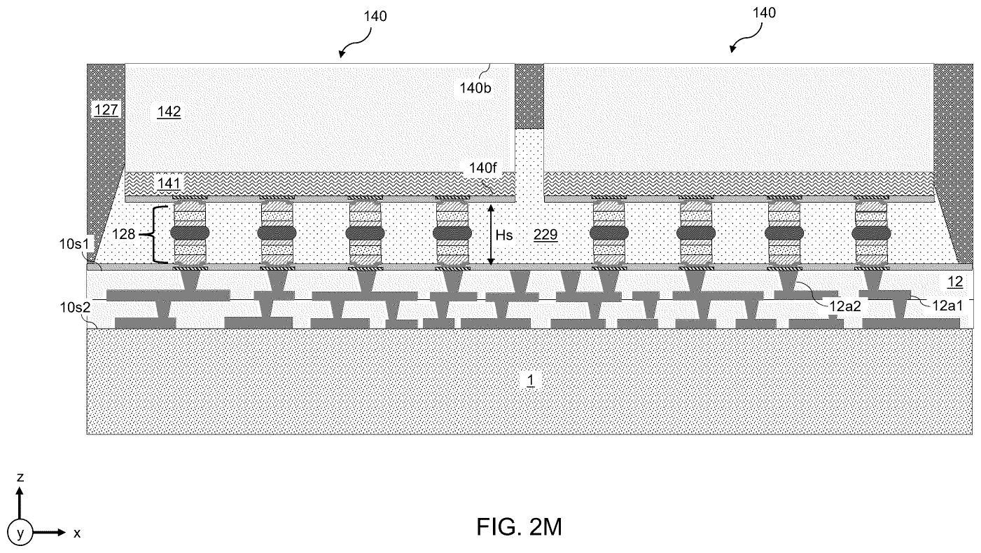

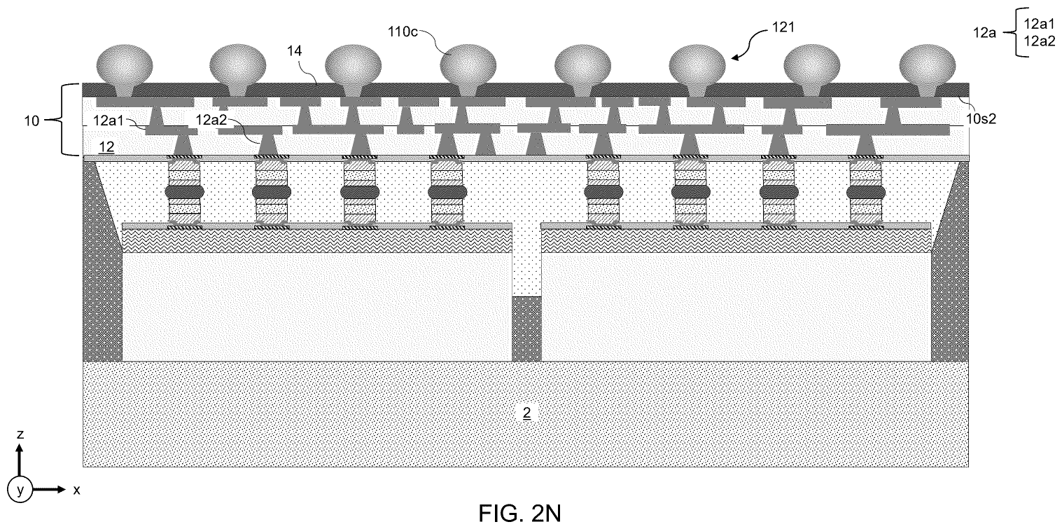

FIGS. 2A-2N are vertical cross-sectional views of intermediate structures in a method of making the semiconductor module 120 according to one more embodiments. FIG. 2A is a vertical cross-sectional view of an intermediate structure including a portion of the interposer 10 (e.g., organic interposer) on a first carrier substrate 1 (e.g., carrier wafer) according to one or more embodiments. The lower passivation layer 14 of the interposer 10 may be formed later in the method of forming the interposer module 120.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 μm to 1 mm, although lesser and greater thicknesses may also be used.

An adhesive layer (not shown) may be applied to the top surface of the first carrier substrate 1. In one embodiment, the first carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. For example, the LTHC layer may include any commercially available LTHC layer. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

A plurality of dielectric layers 12 and plurality of redistribution layers 12a may be alternately formed on the first carrier substrate 1 (e.g., on the adhesive layer on the first carrier substrate 1). It should be noted that although FIG. 2A illustrates two dielectric layers 12 and two redistribution layers 12a, more or fewer dielectric layers 12 and redistribution layers 12a are contemplated by the present disclosure.

Each dielectric layer 12 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 μm to 60 μm, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The layer of metal material may then be patterned by a photolithographic process to form the redistribution layer. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 2A, the interposer bonding pads 16 may then be formed on the uppermost dielectric layer 12 (e.g., on the chip-side surface 10s1 of the interposer 10). In at least one embodiment, the interposer bonding pads 16 may be arranged as a two-dimensional array, which may be a two-dimensional periodic array such as a rectangular periodic array.

Each of the interposer bonding pads 16 may be formed in contact with a respective via 12a2 in the uppermost dielectric layer 12. The interposer bonding pads 16 may include any metallic material that may be bonded to a solder material. The interposer bonding pads 16 may be formed by depositing (e.g., by CVD, PVD or other suitable deposition technique) one or more metal layers including a metal, metal alloys, and/or other metal-containing compounds (e.g., Cu, Al, Ni, Mo, Co, Ru, Ti, Ta, W, TiN, TaN, WN, etc.). The metal layer may then be patterned by a photolithographic process so as to form the interposer bonding pads 16. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

FIG. 2B is a vertical cross-sectional view of an intermediate structure including the upper passivation layer 13 on the chip-side surface 10s1 of the interposer 10, according to one or more embodiments. The upper passivation layer 13 may be formed to have a thickness greater than a thickness of the interposer bonding pads 16. Thus, the upper passivation layer 13 may cover the interposer bonding pads 16.

The upper passivation layer 13 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, chemical mechanical polishing (CMP), etc.) so as to form the upper passivation layer 13.

FIG. 2C is a vertical cross-sectional view of an intermediate structure including openings O₁₃ in the upper passivation layer 13 on the chip-side surface 10s1 of the interposer 10, according to one or more embodiments. The openings O₁₃ may be formed in the upper passivation layer 13 so as to expose the upper surface of the interposer bonding pads 16. The openings O₁₃ may be formed, for example, by using a photolithographic process.

The photolithographic process (e.g., processes) used to form the openings O₁₃ may include forming a patterned photoresist mask (not shown) on the upper passivation layer 13, and etching (e.g., wet etching, dry etching, etc.) the exposed upper surface of the upper passivation layer 13 through openings in the photoresist mask. The photoresist mask may be subsequently removed by ashing, dissolving the photoresist mask or by consuming the photoresist mask during the etch process. After the openings O₁₃ are formed in the upper passivation layer 13, the upper passivation layer 13 (upper solder resist layer) may be cured such as by a thermal cure or ultraviolet (UV) light cure.

FIG. 2D is a vertical cross-sectional view of an intermediate structure including the first seed layer 17 on the upper passivation layer 13 on the chip-side surface 10s1 of the interposer 10, according to one or more embodiments. The first seed layer 17 may be formed, for example, by depositing (e.g., by CVD, PVD or other suitable deposition technique) one or more layers of seed layer material. The seed layer material may include, for example, titanium, copper, etc. As illustrated in FIG. 2D, the seed layer material may be deposited in the openings O₁₃ and onto the upper surface of the interposer bonding pads 16.

FIG. 2E is a vertical cross-sectional view of an intermediate structure including a patterned photoresist layer 5 on the first seed layer 17, according to one or more embodiments. The patterned photoresist layer 5 may be formed for example, by depositing (e.g., by CVD, PVD or other suitable deposition technique) a layer of photoresist material (e.g., UV light sensitive material). The photoresist material may then be exposed to UV light through a photomask containing the pattern to be transferred onto the photoresist material. The photoresist material may then be developed (e.g., by immersion in developer solution) to form the patterned photoresist layer 5. As illustrated in FIG. 2E, the patterned photoresist layer 5 may include openings O₅ substantially aligned with the openings O₁₃ in the upper passivation layer 13.

FIG. 2F is a vertical cross-sectional view of an intermediate structure including first bumps 128aB in the openings O₅ of the patterned photoresist layer 5, according to one or more embodiments. As illustrated in FIG. 2F, the first bumps 128aB may include the first interconnect portion 128a and a first bump solder layer 128ca on the first interconnect portion 128a.

The layers of the first bumps 128aB may be sequentially deposited in the openings O₅ of the patterned photoresist layer 5 in a series of separate deposition steps. The layers of the first bumps 128aB may be deposited, for example, by an electrochemical deposition process, although other suitable deposition techniques may be used.

In particular, the first outer metal layer 128a1 may be deposited in the openings O₅. Then, the first alloy barrier 128a2 may be deposited on the first outer metal barrier 128a1 in the openings O₅. Then, the first inner metal layer 128b3 may be deposited on the first alloy barrier 128a2 in the openings O₅. Then, the first bump solder layer 128ca may be deposited on the first inner metal layer 128b3 in the openings O₅.

FIG. 2G is a vertical cross-sectional view of an intermediate structure including first bumps 128aB on the first seed layer 17, according to one or more embodiments. As illustrated in FIG. 2G, after the forming of the first bumps 128aB, the patterned photoresist layer 5 may be removed. The patterned photoresist layer 5 may be removed, for example, by ashing, dissolving the patterned photoresist layer 5, etc.

Removing the patterned photoresist layer 5 may expose the upper surface of the first seed layer 17. The first bumps 128aB remain standing separately on the first seed layer 17 over the interposer bonding pads 16.

FIG. 2H is a vertical cross-sectional view of an intermediate structure including first bumps 128aB on the first seed layer 17, according to one or more embodiments. As illustrated in FIG. 2H, after the patterned photoresist layer 5 is removed, the exposed portions of the first seed layer 17 may be removed. The exposed portions of the first seed layer 17 may include those portions of the first seed layer 17 that are not covered by the first bumps 128aB.

The exposed portions of the first seed layer 17 may be removed, for example, by an etching process (e.g., wet etching, dry etching, etc.). Removing the exposed portions of the first seed layer 17 may expose the upper passivation layer 13 between the first bumps 128aB.

FIG. 2I is a vertical cross-sectional view of an intermediate structure including the first bumps 128aB after a reflow process, according to one or more embodiments. As illustrated in FIG. 2I, after the exposed portions of the first seed layer 17 are removed, a reflow process may be performed on the first bump solder layer 128ca. The reflow process may be performed, for example, by heating the solder material of the solder layer 128ca to its melting point, then carefully controlling the cooling process. The reflow process may allow for precise control over the shape and size of the first bump solder layer 128ca.

FIG. 2J is a vertical cross-sectional view of an intermediate structure including the semiconductor dies 140 positioned over the interposer 10, according to one or more embodiments. As illustrated in FIG. 2J, the semiconductor dies 140 may include second bumps 128bB. The second bumps 128bB may be substantially similar to the first bumps 128aB. In particular, the second bumps 128bB may include the second interconnect portion 128b and a second bump solder layer 128cb on the second interconnect portion 128b.

The second bumps 128bB may be formed by a process substantially the same as the process of forming the first bumps 128aB described above with respect to FIGS. 2A-2I. In particular, the die bonding pads 146 may be formed on the frontside 140f of the semiconductor die 140 (e.g., see FIG. 2A). The die passivation layer 145 may be formed on the frontside 140f of the semiconductor die 140 and on the die bonding pads 146 (e.g., see FIG. 2B). Openings may be formed in die passivation layer 145 over the die bonding pads 146 (e.g., see FIG. 2C) and the second seed layer 147 may be deposited on the die passivation layer 145 and in the openings (e.g., see FIG. 2D). A patterned photoresist layer may be formed on the second seed layer 147 (e.g., see FIG. 2E) and the second bumps 128bB may be formed in the openings of the patterned photoresist layer (e.g., see FIG. 2F). The patterned photoresist layer may then be removed (e.g., see FIG. 2G), the exposed portions of the second seed layer 147 may be removed (e.g., see FIG. 2H), then a reflow process may be performed on the second bump solder layer 128cb (e.g., see FIG. 2I).

After the second bumps 128bB are formed on the semiconductor dies 140, the semiconductor dies 140 may be positioned over the interposer 10. The semiconductor dies 140 may be positioned over the interposer 10 using an electro-mechanical pick-and-place (PNP) machine. In particular, the semiconductor dies 140 may be positioned over the interposer 10 so that the second bumps 128bB may be substantially aligned with the first bumps 128aB. The second bump solder layer 128cb of the second bumps 128bB may be located adjacent the first bump solder layer 128ca of the first bumps 128aB. In at least one embodiment, the second bump solder layer 128cb of the second bumps 128bB may contact the first bump solder layer 128ca of the first bumps 128aB.

FIG. 2K is a vertical cross-sectional view of an intermediate structure including the semiconductor dies 140 positioned over the interposer 10, according to one or more embodiments. After the second bump solder layer 128cb of the second bumps 128bB is brought into contact with the first bump solder layer 128ca of the first bumps 128aB, a reflow process may be performed. In the reflow process the first bump solder layer 128ca and the second bump solder layer 128cb are melted together to form the solder joint 128c. During the reflow process, a position of the semiconductor dies 140 may be adjusted to ensure that the desired standoff height Hₛ is achieved between the semiconductor dies 140 and the interposer 10.

Each of the semiconductor dies 140 may be bonded to the interposer 10 by one or more of the interconnects 128. In at least one embodiment, the interconnects 128 may include a two-dimensional array of interconnects 128.

FIG. 2L is a vertical cross-sectional view of an intermediate structure including the interposer module underfill layer 229 according to one or more embodiments. The interposer module underfill layer 229 may be applied by depositing and/or injecting an underfill material such as an epoxy-based polymeric material onto the interposer 10. The underfill material may be applied on the interposer 10 so as to be formed under the semiconductor dies 140 and around the interconnects 128. In at least one embodiment, the underfill material may fill substantially all of the gaps between the semiconductor dies 140 and the interposer 10. The underfill material may then be cured to form the interposer module underfill layer 229. The underfill material may be cured, for example, in a box oven for duration in a range from 60 minutes to 120 minutes at a temperature in a range from 120° C. to 180° C. to provide the interposer module underfill layer 229 with a sufficient stiffness and mechanical strength.

FIG. 2M is a vertical cross-sectional view of an intermediate structure including the molding material layer 127, according to one or more embodiments. The molding material layer 127 (e.g., encapsulant layer) may be formed on the semiconductor dies 140 and interposer 10. In at least one embodiment, the molding material layer 127 may be formed by a sequence of an over-molding process and a planarization process. In particular, the molding material layer 127 may include an epoxy polymer material (e.g., an epoxy molding compound (EMC)). The molding material layer 127 may be formed on the interposer 10 and fill in the gaps between the semiconductor dies 140. The molding material layer 127 may encapsulate (e.g., in the x-direction and y-direction) the semiconductor dies 140. The molding material layer 127 may be formed, for example, by a deposition process such as CVD, PECVD, PVD, spin coating, lamination or other suitable deposition technique.

The molding material layer 127 may be deposited so as to completely cover the semiconductor dies 140 and the interposer module underfill layer 229. After the molding material layer 127 has cured, a planarization process may then be used to make an upper surface of the molding material layer 127 substantially coplanar with an upper surface of the semiconductor dies 140. The planarization process may be performed on the upper surface of the molding material layer 127 until an upper surface of the semiconductor dies 140 are exposed. The planarization process may include, for example, a mechanical grinding process and/or a CMP process.

FIG. 2N illustrates a vertical cross-sectional view of an intermediate structure including the plurality of C4 bumps 121, according to one or more embodiments. After the molding material layer 127 has been cured and planarized (e.g., by grinding, CMP, etc.), the intermediate structure may be attached to a second carrier substrate 2. The second carrier substrate 2 may be substantially similar to the first carrier substrate 1. In particular, the second carrier substrate 2 may be attached to the upper surface of the molding material layer 127 and the upper surface of the semiconductor dies 140.

The intermediate structure of FIG. 2M may then be inverted and the first carrier substrate 1 may be detached from the board-side surface 10s2 of the interposer 10. The first carrier substrate 1 may be detached from the interposer 10, for example, by deactivating the adhesive layer (not shown) adhering the first carrier substrate 1 to the interposer 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The interposer lower bonding pads (if present) may then be formed on the lowermost dielectric layer 12 of the interposer 10. The interposer lower bonding pads may be formed using substantially the same materials and substantially the same photolithographic processes as described above for the interposer bonding pads 16. The lower passivation layer 14 may then be formed on the lower dielectric layer 12 of the interposer 10 and over the interposer lower bonding pads (if present).

The lower passivation layer 14 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, chemical mechanical polishing (CMP), etc.) so as to form the lower passivation layer 14. The lower passivation layer 14 may then be etched by a suitable etching process (e.g., by wet etching, dry etching, etc.) to form openings over the redistribution layers 12a in the lower dielectric layer 12 (or over the interposer lower bonding pads if present).

The plurality of C4 bumps 121 may then be formed on the intermediate structure. The C4 bumps 121 may include, for example, solder bumps formed in the openings in the lower passivation layer 14. The C4 bumps 121 may be formed by one or more processes including ball mounting, electroplating, solder printing, solder immersion and solder injection. The C4 bumps 121 may contact the redistribution layers 12a in the lower dielectric layer 12 of the interposer 10 (or the interposer lower bonding pads if present) through the openings in the lower passivation layer 14.

In at least one embodiment, the C4 bumps 121 may be formed by forming one or more underbump metallization (UBM) layers (not shown) on the exposed surface of the redistribution layers 12a (or the exposed surface of the interposer lower bonding pads if present), forming metal pillars on the UBM layers, and then forming the solder bumps on the metal pillars.

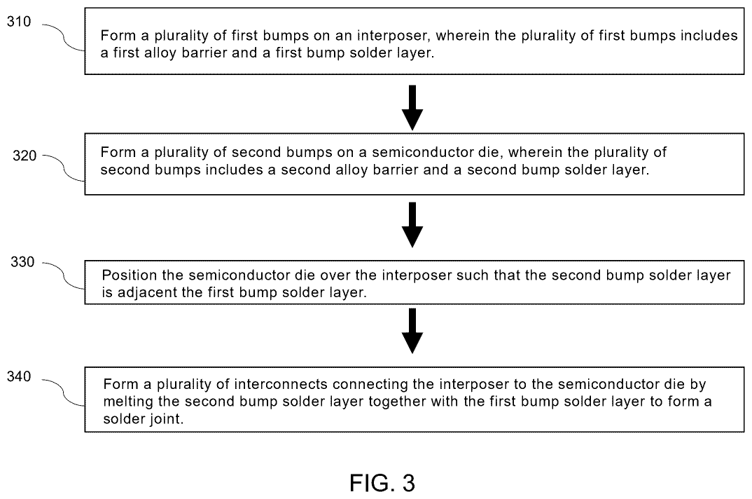

FIG. 3 is a flow chart illustrating a method of making the interposer module 120 according to one or more embodiments. Step 310 includes forming a plurality of first bumps on an interposer, wherein the plurality of first bumps includes a first alloy barrier and a first bump solder layer. Step 320 includes forming a plurality of second bumps on a semiconductor die, wherein the plurality of second bumps includes a second alloy barrier and a second bump solder layer. Step 330 includes positioning the semiconductor die over the interposer such that the second bump solder layer is adjacent the first bump solder layer. Step 340 includes forming a plurality of interconnects connecting the interposer to the semiconductor die by melting the second bump solder layer together with the first bump solder layer to form a solder joint.

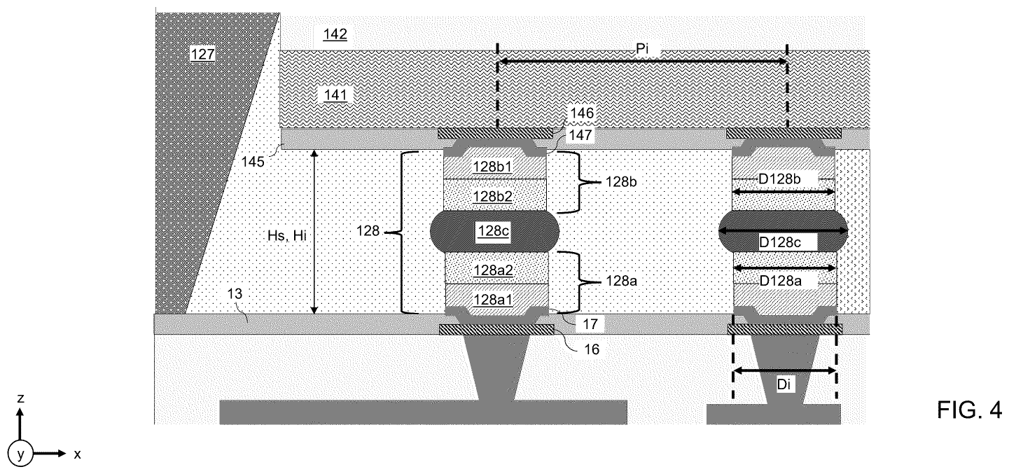

FIG. 4 is a detailed vertical cross-sectional view of the interconnects 128 in the interposer module 120 having a first alternative design according to one more embodiments. As illustrated in FIG. 4, the first alternative design of the interposer module 120 may be substantially the same as the design in the embodiment of FIGS. 1A-1C. However, in contrast to the embodiment of FIGS. 1A-1C, the first alternative design may omit the first inner metal layer 128a3 (e.g., inner copper layer) and the second inner metal layer 128b3 (e.g., inner copper layer). The first interconnect portion 128a may include the first outer metal layer 128a1 and the first alloy barrier 128a2. The second interconnect portion 128b may include the second outer metal layer 128b1 and the second alloy barrier 128b2.

As further illustrated in FIG. 4, the interconnect height Hᵢ (and the standoff height Hₛ) in the first alternative design may be less than the interconnect height Hᵢ in the embodiment of FIGS. 1A-1C. In at least one embodiment, the interconnect height Hᵢ (and the standoff height Hₛ) may be in a range from 5 μm to 35 μm, although an interconnect height Hᵢ less than 5 μm or greater than 35 μm is within the contemplated scope of disclosure. The interconnect pitch Pᵢ in the first alternative design may also be less than the interconnect pitch Pᵢ in the embodiment of FIGS. 1A-1C. In at least one embodiment, the interconnect pitch Pᵢ may be 35 μm or less, but an interconnect pitch Pᵢ greater than 35 μm is within the contemplated scope of disclosure.

The interconnect diameter Dᵢ and the diameter D_{128c} of the solder joint 128c in the first alternative design may be substantially the same as in the embodiment of FIGS. 1A-1C. In at least one embodiment, the interconnect diameter Dᵢ and the diameter D_{128c} of the solder joint 128c in the first alternative design may be less than (e.g., up to about 15% less than) the interconnect diameter Dᵢ and the diameter D_{128c} of the solder joint 128c in the embodiment of FIGS. 1A-1C, respectively.

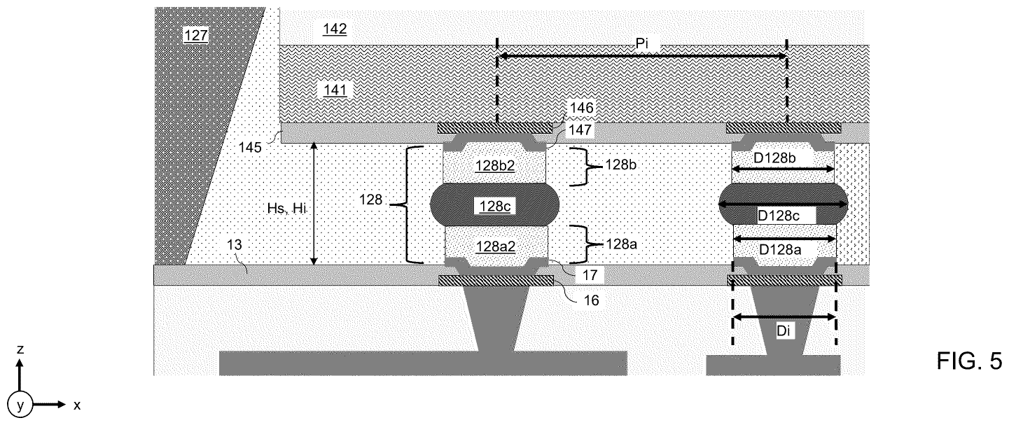

FIG. 5 is a detailed vertical cross-sectional view of the interconnects 128 in the interposer module 120 having a second alternative design according to one more embodiments. As illustrated in FIG. 5, the second alternative design of the interposer module 120 may be substantially the same as the design in the embodiment of FIGS. 1A-1C and the first alternative design in FIG. 4. However, in contrast to the embodiment of FIGS. 1A-1C, the second alternative design may omit the first outer metal layer 128a1 and the second outer metal layer 128b1 in addition to omitting the first inner metal layer 128a3 and the second inner metal layer 128b3. The first interconnect portion 128a may include the first alloy barrier 128a2. The second interconnect portion 128b may include the second alloy barrier 128b2.

As further illustrated in FIG. 5, the interconnect height Hᵢ (and the standoff height Hₛ) in the first alternative design may be less than the interconnect height Hᵢ in the embodiment of FIGS. 1A-1C. In at least one embodiment, the interconnect height Hᵢ (and the standoff height Hₛ) may be in a range from 3 μm to 25 μm, although an interconnect height Hᵢ less than 3 μm or greater than 25 μm is within the contemplated scope of disclosure. The interconnect pitch Pᵢ in the first alternative design may also be less than the interconnect pitch Pᵢ in the embodiment of FIGS. 1A-1C. In at least one embodiment, the interconnect pitch Pᵢ may be 25 μm or less, but an interconnect pitch Pᵢ greater than 25 μm is within the contemplated scope of disclosure.

The interconnect diameter Dᵢ and the diameter D_{128c} of the solder joint 128c in the second alternative design may be substantially the same as in the embodiment of FIGS. 1A-1C. In at least one embodiment, the interconnect diameter Dᵢ and the diameter D_{128c} of the solder joint 128c in the second alternative design may be less than (e.g., up to about 20% less than) the interconnect diameter Dᵢ and the diameter D_{128c} of the solder joint 128c in the embodiment of FIGS. 1A-1C, respectively.

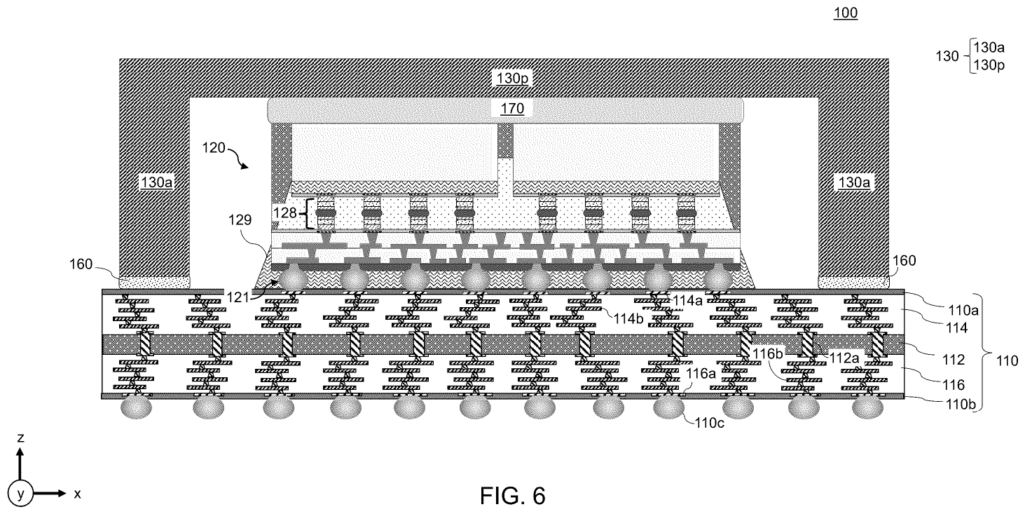

FIG. 6 is a vertical cross-sectional view of a package structure 100 including the interposer module 120 according to one more embodiments.

As illustrated in FIG. 6, the package structure 100 may include a package substrate 110 and the interposer module 120 on the package substrate 110. The package structure 100 may also include a package lid 130 on the interposer module 120. The package lid 130 may include a package lid foot portion 130a attached to the package substrate 110. The package lid 130 may also include a package lid plate portion 130p connected to the package lid foot portion 130a. The package structure 100 may also include a TIM layer 170 between the interposer module 120 and the package lid plate portion 130p.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may electrically couple the package substrate upper bonding pads 114a to the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TIN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may at least partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. The package substrate lower dielectric layer 116 may also include one or more metal interconnect structures 116b. The metal interconnect structures 116b may electrically couple the package substrate lower bonding pads 116a to the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may at least partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate 110. The solder balls 110c may allow the package structure 100 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b. The solder balls 110c of the BGA may be formed in a two-dimensional array on the board-side surface of the package substrate 110. The solder balls 110c may be located, for example, under the package lid foot portion 130a and under the interposer module 120.

As illustrated in FIG. 6, the package substrate 110 may have a width in the x-direction that is greater than a width of the interposer module 120 in the x-direction. The package substrate 110 may also have a length in the y-direction that is greater than a length of the interposer module 120 in the y-direction. The interposer module 120 may be located in a central portion of the package substrate 110.

The interposer module 120 may be attached by the C4 bumps 121 to the package substrate upper bonding pads 114a in the package substrate 110. The C4 bumps 121 may include a metal pillar (not shown) and a solder bump (e.g., SnAg solder bump) on the metal pillar. The solder bump may be collapsed to join the C4 bump 121 to the package substrate upper bonding pads 114a.

A package underfill layer 129 may be formed on the package substrate 110 under and around the interposer module 120. The package underfill layer 129 may also be formed around the C4 bumps 121. The package underfill layer 129 may thereby securely fix the interposer module 120 to the package substrate 110. The package underfill layer 129 may be formed of an underfill material such as an epoxy-based polymeric material. Other suitable materials may be used for the package underfill layer 129.

The TIM layer 170 may be located on the interposer module 120. The TIM layer 170 may include one or more layers. In at least one embodiment, a center of the TIM layer 170 may be substantially aligned with a center of the interposer module 120. In at least one embodiment, the TIM layer 170 may extend laterally (e.g., in the x-y plane) beyond the outer sidewall of the molding material layer 127.

The TIM layer 170 may have a low bulk thermal impedance and high thermal conductivity. The TIM layer 170 may cover an entire area of the upper surface of the interposer module 120. The TIM layer 170 may be attached to the upper surface of the interposer module 120 by a thermally conductive adhesive.

In at least one embodiment, the TIM layer 170 may include one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include graphite, carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 170 are within the contemplated scope of this disclosure.

As further illustrated in FIG. 6, the package lid 130 may be located on the TIM layer 170 and may provide a cover for the interposer module 120. The package lid 130 may be formed, for example, of metal, ceramic or polymer material. Other suitable materials of the package lid 130 may be used.

The package lid foot portion 130a of the package lid 130 may be attached to the package substrate 110. The package lid foot portion 130p may extend in a substantially perpendicular direction from the package lid plate portion 130p. The package lid foot portion 130p may be connected to the package substrate 110 by an adhesive layer 160. The adhesive layer 160 may include, for example, epoxy adhesive or silicone adhesive. Other adhesives are within the contemplated scope of this disclosure.

The package lid plate portion 130p (e.g., main body of the package lid 130) may be connected to the package lid foot portion 130a (e.g., an upper end of the package lid foot portion 130a). In at least one embodiment, the package lid plate portion 130p may be integrally formed as a unit with the package lid foot portion 130a. The package lid plate portion 130p may alternatively be formed separate from the package lid foot portion 130a and attached to the package lid foot portion 130a by an adhesive (not shown). The adhesive may be substantially similar to the adhesive layer 160 described above.

The package lid plate portion 130p may have a plate-shape extending, for example, in an x-y plane in FIG. 6. An outer periphery of the package lid plate portion 130p may be substantially aligned with an outer periphery of the package lid foot portion 130a. The package lid plate portion 130p may be substantially parallel to an upper surface of the package substrate 110. The package lid plate portion 130p may include a central region that is formed over the interposer module 120. In at least one embodiment, a center point (in the x-y plane) of the central region may be substantially aligned with the center point of the interposer module 120 and/or with the center point of the TIM layer 170.

The package substrate 110 may have a substantially rectangular shape having a length in the x-direction greater than the width in y-direction. The package substrate 110 may alternatively have a substantially square shape. Each of the package lid foot portion 130a and interposer module 120 may have an outer shape that is substantially the same as an outer shape of the package substrate 110. Other shapes of the package substrate 110, package lid 130 and interposer module 120 are within the contemplated scope of disclosure. The interposer module 120 may be arranged in a central portion of the package substrate 110 so that a space between the interposer module 120 and the package lid foot portion 130a is substantially uniform around the perimeter of the interposer module 120.

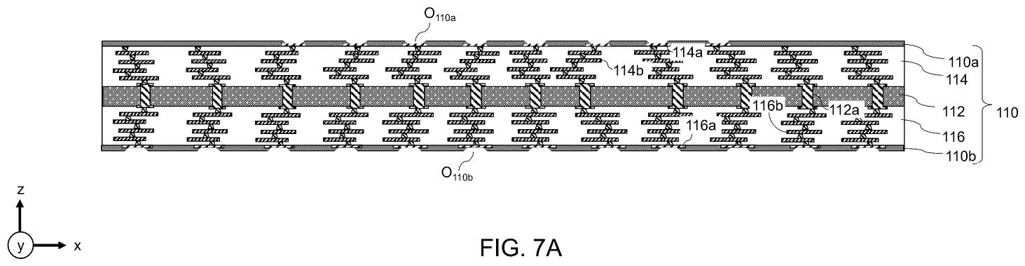

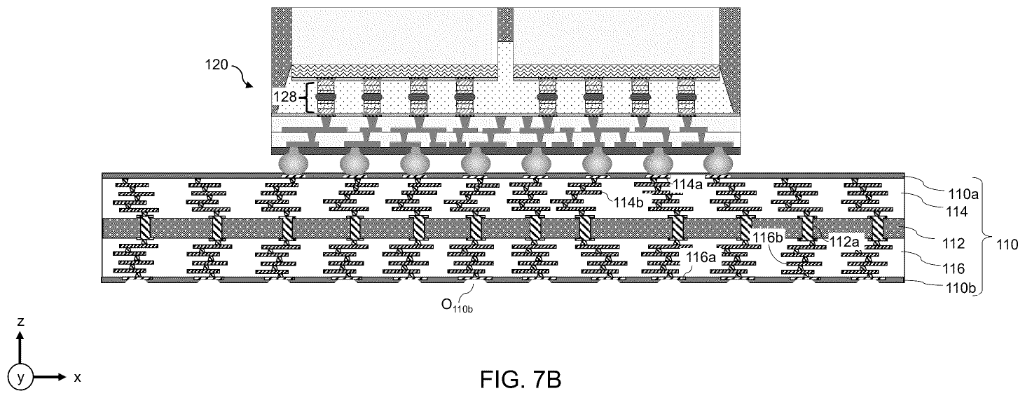

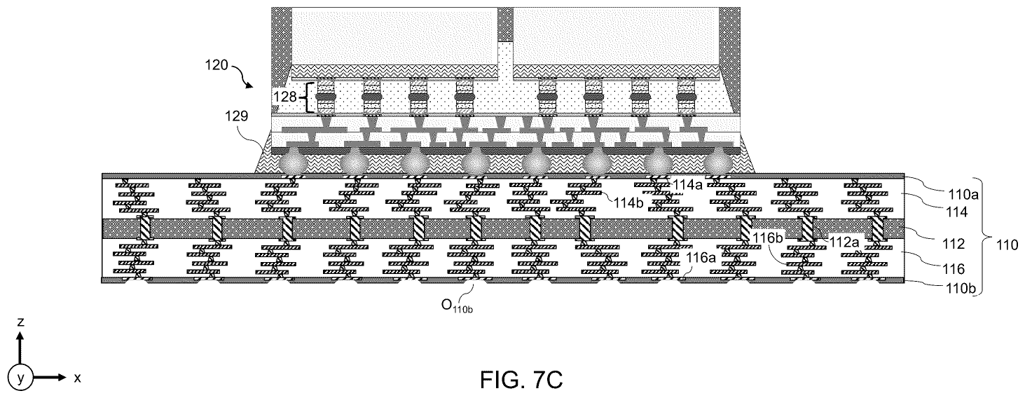

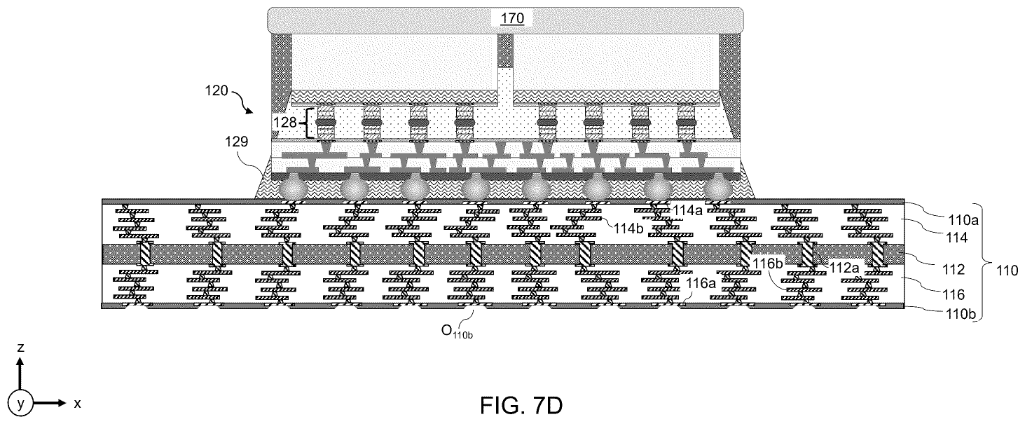

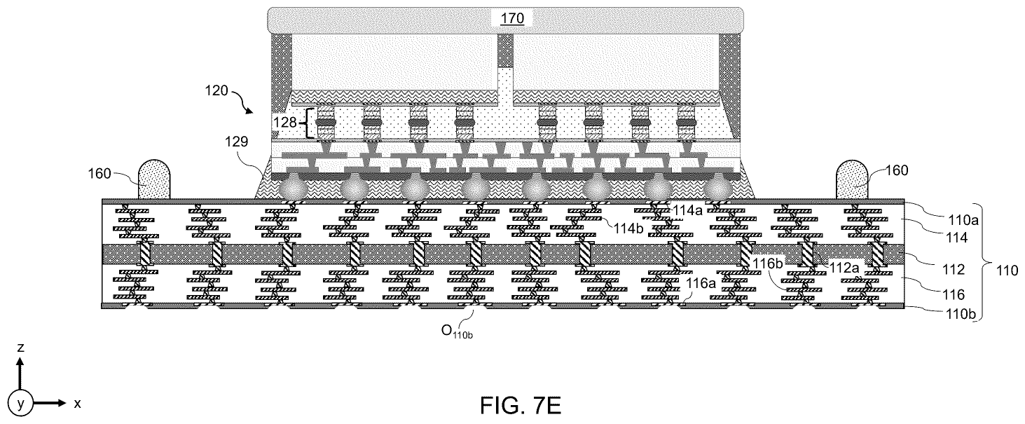

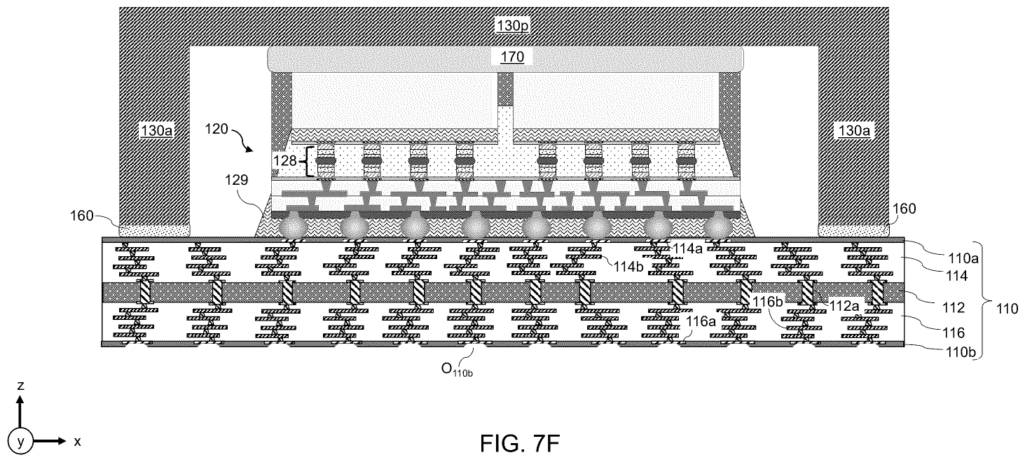

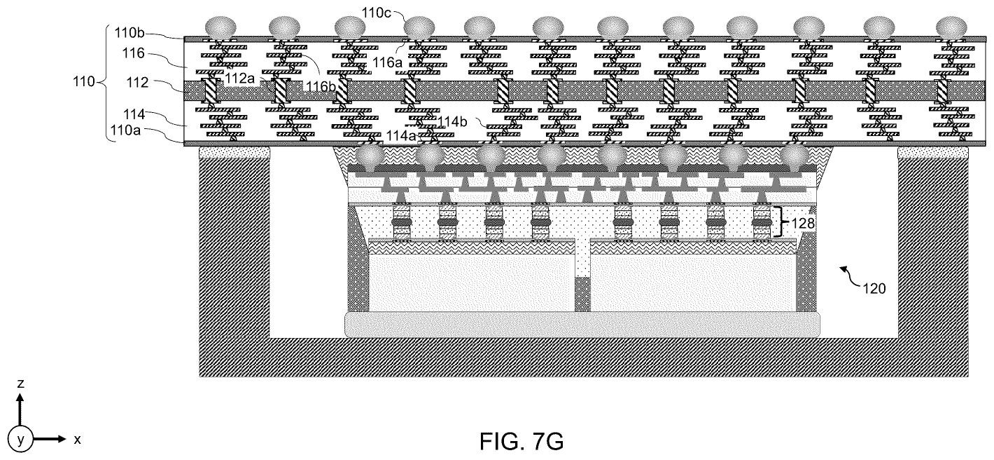

FIGS. 7A-7G illustrate various intermediate structures in a method of forming the package structure 100 according to one or more embodiments. FIG. 7A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum, or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a and package substrate lower passivation layer 110b may each include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination, or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively.

Openings O₁₁₀ₐ may then be formed in the package substrate upper passivation layer 110a so as to expose the upper surface of the package substrate upper bonding pads 114a. Openings O_{110b} may be formed in the package substrate lower passivation layer 110b to expose an upper surface of the package substrate lower bonding pads 116a. The openings O₁₁₀ₐ and the openings O_{110b} may be formed, for example, by using a photolithographic process. In at least one embodiment, the openings O₁₁₀ₐ and the openings O_{110b} may be formed in separate photolithographic processes.

The photolithographic process (e.g., processes) used to form the openings O₁₁₀ₐ may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O_{110b} may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper passivation layer 110a and the openings O_{110b} are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 7B illustrates a vertical cross-sectional view of an intermediate structure in which the interposer module 120 may be mounted on the package substrate 110, according to one or more embodiments. The interposer module 120 may be mounted on the package substrate 110, for example, by a flip chip bonding (FCB) process. The interposer module 120 may be positioned over the package substrate 110, for example, by an electromechanical pick-and-place (PNP) machine. The C4 bumps 121 (e.g., solder bumps) on the interposer module 120 may then be lowered onto the package substrate upper bonding pads 114a through the openings O₁₁₀ₐ (see FIG. 7A) in the package substrate upper passivation layer 110a. The intermediate structure including the interposer module 120 and package substrate 110 may then be heated in order to collapse the C4 bumps 121 and bond the C4 bumps 121 to the package substrate upper bonding pads 114a. In at least one embodiment, laser assisted bonding (LAB) may be used to reflow the C4 bumps 121 so that the interposer module 120 may be attached to the package substrate upper bonding pads 114a.

FIG. 7C illustrates a vertical cross-sectional view of an intermediate structure in which the package underfill layer 129 may be formed on the package substrate 110 according to one or more embodiments. The package underfill layer 129 be formed by applying a liquid material such as an epoxy-based polymeric material to the surface of the package substrate 110. As illustrated in FIG. 7C, the package underfill layer 129 may be formed (e.g., injected) under and around the interposer module 120 and the C4 bumps 121 and onto the package substrate 110. The package underfill layer 129 may then be cured, for example, in a box oven for duration in a range from 60 minutes to 120 minutes at a temperature in a range from 120° C. to 740° C. to provide the package underfill layer 129 with a sufficient stiffness and mechanical strength.

After the package underfill layer 129 is cured, a testing process may be performed to test the intermediate structure (e.g., interposer module 120 and package substrate 110). After the testing process is completed, optional surface mounted devices (SMD) (not shown) such as DRAM devices and multilayer ceramic capacitor (MLCC) devices may be mounted on the surface of the package substrate 110 adjacent the interposer module 120. In an embodiment, a 3D stencil may be used to define which region may be covered by solder paste, and the DRAM devices and MLCC devices may be attached to the package substrate 110 by solder bumps (e.g., a reflow process). The process for attaching the DRAM devices and MLCC devices may be substantially similar as the process described above for attaching the interposer module 120 to the package substrate 110.

FIG. 7D illustrates a vertical cross-sectional view of an intermediate structure in which the TIM layer 170 may be formed on (e.g., attached to) the interposer module 120 according to one or more embodiments. The TIM layer 170 may be applied to have a width in the x-direction and length in the y-direction that are less than the completed width and length of the TIM layer 170, since the pressing of the package lid 130 will cause a deformation of the TIM layer 170 and lateral spreading of the TIM layer 170 in the x-direction and y-direction.

In at least one embodiment, a thermally conductive adhesive may or may not be applied to the upper surface of the interposer module 120, depending upon the type of TIM layer 170 is being used. A material of the TIM layer 170 may be dispensed in the form of a liquid (e.g., grease, gel, paste, etc.) onto the upper surface of the interposer module 120 (or onto the thermally conductive adhesive if present). In embodiments in which the TIM layer 170 includes a solid material, the TIM layer 170 may be pressed onto the interposer module 120 or onto the adhesive if present.

After the TIM layer 170 is formed on the interposer module 120, additional processes may be performed in preparation for attaching the package lid 130 on the package substrate. Such processes may include, for example, flux cleaning, pre-bake and plasma processes.

FIG. 7E illustrates a vertical cross-sectional view of an intermediate structure in which the adhesive layer 160 may be applied to the package substrate 110 according to one or more embodiments. The adhesive layer 160 may be dispensed onto the package substrate 110 with a dispensing tool (e.g., automated dispensing tool). The dispensing tool may dispense the adhesive layer 160 in a frame shape around the interposer module 120. At the time of application, the adhesive layer 160 may be sufficiently rigid so as to form a semi-solid bead on the surface of the package substrate 110. In at least one embodiment, a viscosity of the adhesive layer 160 at the time of application may be 50,000 centipoise (cp) or greater. The shape of the semi-solid bead may remain substantially unchanged between the time of application by the dispensing tool and the later time of attaching the package lid 130. The location of the frame shape of the adhesive layer 160 may correspond to a location of the foot portion 130a of the package lid 130. A pressing of the package lid 130 onto the adhesive layer 160 may deform the adhesive layer 160.

FIG. 7F illustrates a vertical cross-sectional view of an intermediate structure in which the package lid 130 may be attached to (e.g., mounted on) the package substrate 110 according to one or more embodiments. In at least one embodiment, the package substrate 110 with the interposer module 120 may be placed on a surface. The package lid 130 may then be positioned over the package substrate 110, for example, by an electromechanical pick-and-place (PNP) machine. The package lid 130 may then be lowered down over the interposer module 120 and onto the package substrate 110. The foot portion 130a of the package lid 130 may then be aligned with the adhesive layer 160 formed on the package substrate 110.

The package lid 130 may then be pressed downward on to the TIM layer 170 by applying a pressing force down onto the package lid 130 so that the foot portion 130a of the package lid 130 may be attached to the package substrate 110 through the adhesive layer 160. In at least one embodiment, the pressing force may cause the package lid plate portion 130p to compress the TIM layer 170. The package lid 130 may then be clamped to the package substrate 110 for a period of sufficient duration to allow the adhesive layer 160 to cure and form a secure bond between the package substrate 110 and the package lid 130. In at least one embodiment, the adhesive layer 160 is a snap-cure adhesive that may be cured by exposure to ultraviolet (UV) light.

The clamping of the package lid 130 to the package substrate 110 may additionally or alternatively be performed, for example, by using a heat clamp module. The heat clamp module may apply a uniform force across the upper surface of the package lid 130. In one or more embodiments, the heat clamp module may apply the pressing force to the package lid 130. The adhesive layer 160 may additionally or alternatively be cured, for example, in a box oven to provide the adhesive layer 160 with sufficient stiffness and mechanical strength.

FIG. 7G illustrates a vertical cross-sectional view of an intermediate structure in which a plurality of solder balls 110c may be formed on the package substrate 110 according to one or more embodiments. The plurality of solder balls 110c may be formed on the package substrate lower bonding pads 116a through the openings O_{110b} in the package substrate lower passivation layer 110b (see FIG. 7A). The solder balls 110c may be formed, for example, by an electroplating process. Other methods of forming the solder balls 110c are within the contemplated scope of disclosure. The solder balls 110c may be formed, for example, so as to be located under the foot portion 130a and under the interposer module 120 and therebetween. The plurality of solder balls 110c may constitute a ball-grid array (BGA) that may allow the package structure 100 to be securely mounted (e.g., by surface mount technology (SMT)) on a substrate such as a printed circuit board and electrically coupled to the substrate.

At this point, one or more optional integrated passive devices (IPDs) (e.g., passive components) (not shown) may be mounted on the board-side surface of the package substrate 110. The optional IPDs may be mounted in a process similar to the mounting process for the SMD described above. In particular, the mounting process may include a solder reflow process for electrically coupling the IPDs to the package substrate 110. After the optional IPDs are mounted on the package substrate 110, additional processes may be used to clean the package substrate 110 and maintain the surface of the package substrate 110. Such processes may include, for example, flux cleaning, pre-bake and plasma processes. An IPD underfill layer (e.g., passive component underfill) may then be applied to the package substrate 110 and under and around the IPDs. The IPD underfill layer may include a material substantially the same as the material of the package underfill layer 129. The IPD underfill layer may also be applied and cured in a manner substantially similar to the manner of applying and curing the package underfill layer 129 described above.

After the optional IPD underfill layer is cured, one or more processes may be performed prior to final testing. The processes may include, for example, one or more inspections such as an inspection by an optical inspection system (e.g., ICOS, HEXA, etc.) and a final visual inspection. These inspections may provide a sanity check (e.g., checking z-height, package appearance, etc.) of the completed package structure 100. A final testing process may then be performed on the package structure 100.

Referring to FIGS. 1A-7G, an interposer module 120 may include an interposer 10, a semiconductor die 140 on the interposer 10, and a plurality of interconnects 128 connecting the interposer 10 to the semiconductor die 140, wherein the plurality of interconnects 128 may include a first interconnect portion 128a including a first alloy barrier 128a2, a second interconnect portion 128b including a second alloy barrier 128b2, and a solder joint 128c connecting the first interconnect portion 128a to the second interconnect portion 128b.

In one embodiment, each of the first alloy barrier 128a2 and the second alloy barrier 128b2 may include one of an iron-based binary alloy or a tungsten-based binary alloy. In one embodiment, the iron-based binary alloy may include iron in a range from 50 wt % to 90 wt %, and the tungsten-based binary alloy may include tungsten in a range from 40 wt % to 50 wt %. In one embodiment, the iron-based binary alloy may include one of FeNi or FeCo, and the tungsten-based binary alloy may include one of NiW or CoW. In one embodiment, each of the first alloy barrier 128a2 and the second alloy barrier 128b2 may include a thickness in a range from 1 μm to 5 μm. In one embodiment, a pitch Pᵢ between the plurality of interconnects 128 may be 40 μm or less. In one embodiment, the first interconnect portion 128a may further include a first outer metal layer 128a1, and a first inner metal layer 128a3 and the first alloy barrier 128a2 may be between the first outer metal layer 128a1 and the first inner metal layer 128a3, and the second interconnect portion 128b may further include a second outer metal layer 128b1, and a second inner metal layer 128b3 and the second alloy barrier 128b2 may be between the second outer metal layer 128b1 and the second inner metal layer 128b3. In one embodiment, the first alloy barrier 128a2 may contact the solder joint 128c, and the second alloy barrier 128b2 may contact the solder joint 128c. In one embodiment, the interposer module 120 may further include a first intermetallic compound (IMC) layer 129a on an interposer side of the solder joint 128c, and a second IMC layer 129b on a semiconductor die side of the solder joint 128c. In one embodiment, a combined thickness of the second IMC layer 129b and the first IMC layer 129a may be less than or equal to about 10% of a thickness of the solder joint 128c. In one embodiment, a length of solder wetting on a sidewall of the first alloy barrier 128a2 may be less than or equal to about 10% of a thickness of the first alloy barrier 128a2, and a length of solder wetting on a sidewall of the second alloy barrier 128b2 may be less than or equal to about 10% of a thickness of the second alloy barrier 128b2. In one embodiment, the first interconnect portion 128a further may include a first outer metal layer 128a1, and the first alloy barrier 128a2 may contact the first outer metal layer 128a1 and the solder joint 128c, and the second interconnect portion 128b further may include a second outer metal layer 128b1, and the second alloy barrier 128b2 may contact the second outer metal layer 128b1 and the solder joint 128c. In one embodiment, the interposer 10 may include an interposer bonding pad 16, the semiconductor die 140 may include a semiconductor die bonding pad 146, and an interconnect 128 of the plurality of interconnects 128 may connect the interposer bonding pad 16 to the semiconductor die bonding pad 146. In one embodiment, the interposer 10 may further include a first seed layer 17 on the interposer bonding pad 16, and the first alloy barrier 128a2 may contact the first seed layer 17 and the solder joint 128c, and the semiconductor die 140 may further include a second seed layer 147 on the semiconductor die bonding pad 146, and the second alloy barrier 128b2 may contact the second seed layer 147 and the solder joint 128c.

Referring again to FIGS. 1A-7G, a method of forming an interposer module 120 may include forming a plurality of first bumps 128aB on an interposer 10, wherein the plurality of first bumps 128aB may include a first alloy barrier 128a2 and a first bump solder layer 128ca, forming a plurality of second bumps 128bB on a semiconductor die 140, wherein the plurality of second bumps 128bB may include a second alloy barrier 128b2 and a second bump solder layer 128cb, positioning the semiconductor die 140 over the interposer 10 such that the second bump solder layer 128cb may be adjacent the first bump solder layer 128ca, and forming a plurality of interconnects 128 connecting the interposer 10 to the semiconductor die 140 by melting the second bump solder layer 128cb together with the first bump solder layer 128ca to form a solder joint 128c.

In one embodiment, the forming of the plurality of first bumps 128aB may include forming a first outer metal layer 128a1, forming the first alloy barrier 128a2 on the first outer metal layer 128a1, forming a first inner metal layer 128a3 on the first alloy barrier 128a2, and forming the first bump solder layer 128ca on the first inner metal layer 128a3. In one embodiment, the forming of the plurality of second bumps 128bB may include forming a second outer metal layer 128b1, forming the second alloy barrier 128b2 on the second outer metal layer 128b1, forming a second inner metal layer 128b3 on the second alloy barrier 128b2, and forming the second bump solder layer 128cb on the second inner metal layer 128b3. In one embodiment, the forming of the first alloy barrier 128a2 may include forming the first alloy barrier 128a2 to have a thickness in a range from 1 μm to 5 μm, and the forming of the second alloy barrier 128b2 may include forming the second alloy barrier 128b2 to have a thickness in a range from 1 μm to 5 μm. In one embodiment, the forming of the plurality of first bumps 128aB may include forming the plurality of first bumps 128aB to have a pitch Pᵢ of 40 μm or less, and the forming a plurality of second bumps 128bB may include forming the plurality of second bumps 128bB to have a pitch Pᵢ of 40 μm or less.

Referring again to FIGS. 1A-7G, a package structure 100 may include a package substrate, and an interposer module 120 on the package substrate 110, including an interposer 10, a semiconductor die 140 on the interposer 10, and a plurality of interconnects 128 connecting the interposer 10 to the semiconductor die 140, and including a solder joint 128c and a pair of alloy barriers 128a2, 128b2 on opposing sides of the solder joint 128c. The package structure 100 may further include a thermal interface material (TIM) layer 170 on the interposer module 120, and a package lid 130 including a package lid plate portion 130p on the TIM layer 170, and a package lid foot portion 130a projecting from the package lid plate portion 130p and attached to the package substrate 110.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interposer module comprising:
an interposer;
a semiconductor die on the interposer; and
a plurality of interconnects connecting the interposer to the semiconductor die, wherein the plurality of interconnects comprises:
a first interconnect portion comprising a first alloy barrier;
a second interconnect portion comprising a second alloy barrier; and
a solder joint connecting the first interconnect portion to the second interconnect portion.

2. The interposer module of claim 1, wherein each of the first alloy barrier and the second alloy barrier comprises one of an iron-based binary alloy or a tungsten-based binary alloy.

3. The interposer module of claim 2, wherein the iron-based binary alloy comprises iron in a range from 50 wt % to 90 wt %, and the tungsten-based binary alloy comprises tungsten in a range from 40 wt % to 50 wt %.

4. The interposer module of claim 2, wherein the iron-based binary alloy comprises one of FeNi or FeCo, and the tungsten-based binary alloy comprises one of NiW or CoW.

5. The interposer module of claim 1, wherein each of the first alloy barrier and the second alloy barrier comprises a thickness in a range from 1 μm to 5 μm.

6. The interposer module of claim 1, wherein a pitch between the plurality of interconnects is 40 μm or less.

7. The interposer module of claim 1, wherein the first interconnect portion further comprises a first outer metal layer and a first inner metal layer, and the first alloy barrier is between the first outer metal layer and the first inner metal layer, and the second interconnect portion further comprises a second outer metal layer and a second inner metal layer, and the second alloy barrier is between the second outer metal layer and the second inner metal layer.

8. The interposer module of claim 1, wherein the first alloy barrier contacts the solder joint, and the second alloy barrier contacts the solder joint.

9. The interposer module of claim 8, further comprising:
a first intermetallic compound (IMC) layer on an interposer side of the solder joint; and
a second IMC layer on a semiconductor die side of the solder joint.

10. The interposer module of claim 9, wherein a combined thickness of the second IMC layer and the first IMC layer is less than or equal to about 10% of a thickness of the solder joint.

11. The interposer module of claim 8, wherein a length of solder wetting on a sidewall of the first alloy barrier is less than or equal to about 10% of a thickness of the first alloy barrier, and a length of solder wetting on a sidewall of the second alloy barrier is less than or equal to about 10% of a thickness of the second alloy barrier.

12. The interposer module of claim 1, wherein the first interconnect portion further comprises a first outer metal layer and the first alloy barrier contacts the first outer metal layer and the solder joint, and the second interconnect portion further comprises a second outer metal layer and the second alloy barrier contacts the second outer metal layer and the solder joint.

13. The interposer module of claim 1, wherein the interposer includes an interposer bonding pad, the semiconductor die includes a semiconductor die bonding pad, and an interconnect of the plurality of interconnects connects the interposer bonding pad to the semiconductor die bonding pad, and
wherein the interposer further comprises a first seed layer on the interposer bonding pad, and the first alloy barrier contacts the first seed layer and the solder joint, and the semiconductor die further comprises a second seed layer on the semiconductor die bonding pad, and the second alloy barrier contacts the second seed layer and the solder joint.

14. A method of forming an interposer module, the method comprising:
forming a plurality of first bumps on an interposer, wherein the plurality of first bumps comprises a first alloy barrier and a first bump solder layer;
forming a plurality of second bumps on a semiconductor die, wherein the plurality of second bumps comprises a second alloy barrier and a second bump solder layer;
positioning the semiconductor die over the interposer such that the second bump solder layer is adjacent the first bump solder layer; and
forming a plurality of interconnects connecting the interposer to the semiconductor die by melting the second bump solder layer together with the first bump solder layer to form a solder joint.

15. The method of claim 14, wherein the forming of the plurality of first bumps comprises:
forming a first outer metal layer;
forming the first alloy barrier on the first outer metal layer;
forming a first inner metal layer on the first alloy barrier; and
forming the first bump solder layer on the first inner metal layer.

16. The method of claim 15, wherein the forming of the plurality of second bumps comprises:
forming a second outer metal layer;
forming the second alloy barrier on the second outer metal layer;
forming a second inner metal layer on the second alloy barrier; and
forming the second bump solder layer on the second inner metal layer.

17. The method of claim 16, wherein the forming of the first alloy barrier comprises forming the first alloy barrier to have a thickness in a range from 1 μm to 5 μm, and the forming of the second alloy barrier comprises forming the second alloy barrier to have a thickness in a range from 1 μm to 5 μm.

18. The method of claim 14, wherein the forming of the plurality of first bumps comprises forming the plurality of first bumps to have a pitch of 40 μm or less, and the forming a plurality of second bumps comprises forming the plurality of second bumps to have a pitch of 40 μm or less.

19. A package structure, comprising:
a package substrate; and
an interposer module on the package substrate, comprising:
an interposer;
a semiconductor die on the interposer; and
a plurality of interconnects connecting the interposer to the semiconductor die, and comprising a solder joint and a pair of alloy barriers on opposing sides of the solder joint.

20. The package structure of claim 19, further comprising:
a thermal interface material (TIM) layer on the interposer module; and
a package lid comprising:
a package lid plate portion on the TIM layer; and
a package lid foot portion projecting from the package lid plate portion and attached to the package substrate.
